(19) United States
(12) Patent Application Publication
(10) Pub. No.: US 2024/0304718 A1
(43) Pub. Date: Sep. 12, 2024

(54) Vertical Power Semiconductor Device and Manufacturing Method Thereof

(71) Applicant: Diodes Incorporated, Plano, TX (US)

(72) Inventors: Chiao-Shun CHUANG, New Tapei City (TW); TaChuan KUO, New Tapei City (TW)

(21) Appl. No.: 18/373,930

(22) Filed: Sep. 27, 2023

(30) Foreign Application Priority Data
Mar. 9, 2023 (CN) 202310232469.7

(51) Int. Cl. H01L 29/78; H01L 29/08; H01L 29/10; H01L 29/417; H01L 29/66

(52) U.S. Cl. CPC H01L 29/7813; H01L 29/086; H01L 29/0878; H01L 29/1095; H01L 29/41766; H01L 29/66734

(57) ABSTRACT

A vertical power semiconductor device includes a semiconductor material layer having a first surface and a second surface opposite each other. A first electrode structure and a second electrode structure are arranged in the semiconductor material layer, extending from the first surface to the second surface. A first doped region having a first conductivity type is arranged between the first and second electrode structures. A second doped region having a second conductivity type is in the first doped region. The second doped region is close to the bottom of the first doped region and separated from the first surface. A third doped region having the second conductivity type is between the bottom of the first doped region and the second surface. A conductive plug is between the first and second electrode structures and separated from the third doped region. A method for manufacturing the semiconductor device is also provided.

### CROSS-REFERENCE TO RELATED DISCLOSURES

This patent disclosure claims priority to Chinese Patent Application No. 202310232469.7, filed on Mar. 9, 2023 and entitled “Vertical power semiconductor device and manufacturing method thereof,” which is hereby incorporated by reference herein as if reproduced in its entirety.

### TECHNICAL FIELD

The present disclosure relates to the field of semiconductors, and more particularly, to semiconductor structures and methods of fabricating the same. In an embodiment, a vertical power semiconductor device with a Schottky barrier diode structure is provided.

### BACKGROUND

Compared with a Schottky barrier diode (SBD), a metal-oxide semi-field effect transistor (MOSFET) usually has a higher forward voltage and longer reverse recovery time, resulting in the MOSFET having a higher number and longer switching time. Connecting the SBD and the MOSFET can achieve the purpose of reducing the power consumption and switching time of the MOSFET. In existing technologies, this purpose may be achieved by connecting an SBD chip and a MOSFET in parallel and then packaging, or by placing an SBD and a MOSFET in adjacent planar areas of the same chip and connecting the SBD and the MOSFET. However, packaging the SBD chip with the MOSFET will increase the cost. On the other hand, placing the SBD and the MOSFET in adjacent areas of the same chip requires additional chip area, which becomes a technical bottleneck in device miniaturization.

### SUMMARY

Technical advantages are generally achieved, by embodiments of this disclosure which describe a vertical power semiconductor device and manufacturing method thereof.

Embodiments of the present disclosure relate to a vertical power semiconductor device. The vertical power semiconductor device includes: a semiconductor material layer having a first surface and a second surface opposite to each other; a first electrode structure located in the semiconductor material layer and extending from the first surface to the second surface; a second electrode structure located in the semiconductor material layer and adjacent to the first electrode structure; a conductive plug located between the first electrode structure and the second electrode structure; a first doped region arranged at least in the semiconductor material layer close to the first surface and between the first electrode structure and the second electrode structure, the first doped region having a first conductivity type; a second doped region located in the first doped region between the first electrode structure and the second electrode structure, the second doped region having a second conductivity type, and the second doped region being close to a bottom of the first doped region and separated from the first surface; and a third doped region in the semiconductor material layer between the bottom of the first doped region and the second surface, the third doped region having the second conductive type, a doping concentration of the second doped region being greater than a doping concentration of the third doped region, and the conductive plug being separated from the third doped region.

Embodiments of the present disclosure relate to a method of manufacturing a vertical power semiconductor device. The method includes: forming a first trench and a second trench in a semiconductor material layer, the semiconductor material layer comprising a lightly doped region of a first conductivity type; forming a first electrode structure and a second electrode structure in the first trench and the second trench, respectively; forming a first doped region, a second doped region and a third doped region in the semiconductor material layer between the first electrode structure and the second electrode structures, wherein the first doped region has a first conductivity type and adjoins an upper surface of the semiconductor material layer, the second doped region has a second conductivity type and adjoins a bottom of the first doped region, and the third doped region has the first conductivity type and adjoins the bottom of the second doped region. A doping concentration of the third doped region is greater than a doping concentration of the lightly doped region. The method further includes forming a conductive plug between the first electrode structure and the second electrode structure, wherein the conductive plug extends downward from the upper surface of the semiconductor material layer and contacts the first doped region, the second doped region and the third doped region. The conductive plug ends in the third doped region and is separated from the lightly doped region.

### BRIEF DESCRIPTION OF THE DRAWINGS

Embodiments of the present disclosure may be better understood from the following detailed description when read with accompanying drawings. It should be noted that the various structures may not be drawn to scale. In fact, the dimensions of the various structures may be arbitrarily enlarged or reduced for clarity of discussion.

The technical solutions and beneficial effects of the present disclosure will be made apparent through the detailed description of embodiments of the present disclosure in conjunction with the accompanying drawings, in which:

FIG. 1 is a diagram of a cross-sectional view of a vertical power semiconductor device according to certain embodiments of the present disclosure;

FIG. 2 is a diagram of a top view of a vertical power semiconductor device according to certain embodiments of the present disclosure;

FIGS. 3, 4, 5, 6, 7, 8, 9, 10, 11, 12, 13, 14, 15 and 16 are diagrams showing an example of one or more stages in a manufacturing method of a vertical power semiconductor device according to certain embodiments of the present disclosure;

FIGS. 17, 18, 19, 20, 21, 22 and 23 are diagrams showing another example of one or more stages in a manufacturing method of a vertical power semiconductor device according to certain embodiments of the present disclosure;

FIGS. 24, 25 and 26 are diagrams showing yet another example of one or more stages in a manufacturing method of a vertical power semiconductor device according to certain embodiments of the present disclosure; and

FIGS. 27, 28 and 29 are diagrams showing yet another example of one or more stages in a manufacturing method of a vertical power semiconductor device according to certain embodiments of the present disclosure.

The same or similar components are labeled with the same reference numerals in the drawings and detailed description. Embodiments of the present disclosure will be readily understood from the following detailed description taken in conjunction with the accompanying drawings.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

The following disclosure provides various different embodiments or examples for implementing different features of the presented subject matter. Specific embodiments of components and configurations are described below. Certainly, these are examples only and are not intended to be limiting. In this disclosure, references to forming a first feature over or on a second feature may include embodiments where the first and second features are formed in direct contact, and may also include embodiments where an additional feature is formed between the first feature and the second feature such that the first feature and the second feature may not be in direct contact. In addition, the present disclosure may repeat reference signs and/or letters in various embodiments. Such repetition is for simplicity and clarity and does not in itself indicate a relationship between the various embodiments and/or configurations discussed.

Embodiments of the present disclosure are discussed in detail below. It should be appreciated, however, that the present disclosure provides applicable concepts that can be embodied in a wide variety of specific contexts. The specific embodiments discussed herein are illustrative only, and do not limit the scope of the present disclosure.

Embodiments of the present disclosure provide a vertical power semiconductor device and a manufacturing method thereof. Compared with conventional vertical power semiconductor devices, the vertical power semiconductor device of embodiments of the present disclosure has a semiconductor and metal junction structure similar to a Schottky barrier diode (SBD), and can reduce forward voltage and shorten reverse recovery time, thereby achieving the effect of reducing power consumption and shortening switching time. In addition, the vertical power semiconductor device of the embodiments of the present disclosure may be integrated with a SBD structure in a single chip, which can achieve the effect of reducing the total surface area of the device and the total process cost, compared with a semiconductor packaging structure in which an SBD chip and a transistor chip are connected in parallel.

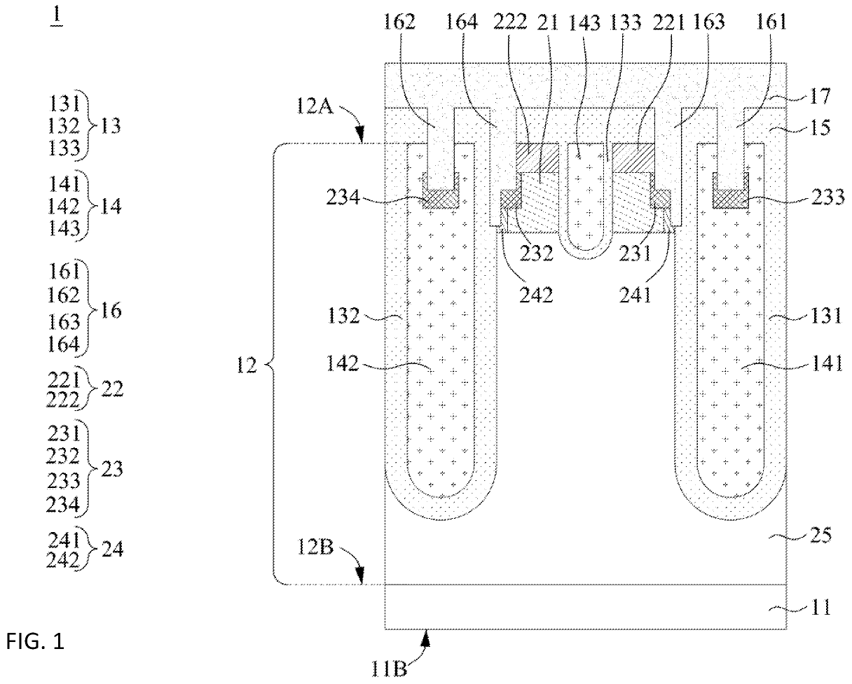

FIG. 1 is a cross-sectional view of a vertical power semiconductor device 1 according to some embodiments of the present disclosure. The vertical power semiconductor device 1 may be a semiconductor power device of various types or manufactured by various technologies. For example, the vertical power semiconductor device may include a power metal-oxide-semiconductor field-effect transistor (MOSFET), a double-diffused MOSFET (DMOSFET), an insulated-gate bipolar transistor (IGBT), or a junction gate field-effect transistor (JFET). Specifically, the vertical power semiconductor device 1 may have a vertical current conduction path. For example, the current of the vertical power semiconductor device 1 may flow in a direction that is perpendicular to the active surface of the vertical power semiconductor device 1. In an example, the current of the vertical power semiconductor device 1 may be conducted vertically passing through the vertical power semiconductor device 1.

In some embodiments, the vertical power semiconductor device 1 may include a semiconductor material layer 12, an electrode 14 (including shield electrodes 141 and 142, and a gate electrode 143), conductive plugs 16 (e.g., conductive plugs 161, 162, 163, 164, which are collectively referred to as the conductive plugs 16), and doped regions 21, 22, 23, 24 and 25.

The semiconductor material layer 12 may include, for example, N type or P type single crystal silicon material, epitaxial silicon material, silicon carbide (SiC), germanium (Ge), silicon germanium (SiGe), gallium nitride (GaN), gallium arsenide (GaAs), gallium arsenide phosphorus (GaAsP) or other semiconductor materials. In some embodiments, the semiconductor material layer 12 may have epitaxial silicon material of the lightly doped region 25 of a first type. For the convenience of description, the N type will be used as an example of the first type in the following description. However, the present disclosure is not limited thereto, and the N type (first type) or the P type (second type) may be used for the semiconductor material layer 12 according to the conductivity type of the vertical power semiconductor device 1.

The semiconductor material layer 12 may have a surface 12A and a surface 12B opposite to the surface 12A. In some embodiments, the surface 12A and the surface 12B may be located on an opposite side of a drain contact region 11. In some embodiments, the surface 12A and the surface 12B may be horizontal planes. For the convenience of description, the direction perpendicular to the surface 12A and the surface 12B is defined as the vertical direction, and the direction perpendicular to the vertical direction is defined as the horizontal direction. In some embodiments, the surface 12A may be an active surface of the semiconductor material layer 12.

The shield electrodes 141 and 142 may be located in the semiconductor material layer 12 and extend from the surface 12A toward the surface 12B of the semiconductor material layer 12. The shield electrodes 141 and 142 are separate from each other. In some embodiments, the shield electrodes 141 and 142 may extend along the vertical direction and be parallel to each other. In some embodiments, the shield electrodes 141 and 142 may have approximately the same depth.

The gate electrode 143 may be located in the semiconductor material layer 12 and extend from the surface 12A of the semiconductor material layer 12 toward the surface 12B. In some embodiments, the gate electrode 143 may extend along the vertical direction and be parallel to the shield electrodes 141 and 142. In some embodiments, the gate electrode 143 may be close to the shield electrode 141 or 142. In some embodiments, the gate electrode 143 may be provided between the shield electrodes 141 and 142. The gate electrode 143 and the shield electrodes 141 and 142 are provided separately from one another. In embodiments, the depth of the gate electrode 143 is smaller than that of the shield electrode 14.

The vertical power semiconductor device 1 may also include an in-trench dielectric layer 13 (e.g., in-trench dielectric layers 131, 132, 133, which are hereinafter collectively referred to as the in-trench dielectric layer 13), in order to electrically isolate the electrode 14 from the semiconductor material layer 12. In some implementations, the in-trench dielectric layer 131 surrounds the shield electrode 141, the in-trench dielectric layer 132 surrounds the shield electrode 142, and the in-trench dielectric layer 133 surrounds the shield electrode 143. In other words, the shield electrode 141 is separated from the semiconductor material layer 12 through the in-trench dielectric layer 131, the shield electrode 142 is separated from the semiconductor material layer 12 through the in-trench dielectric layer 132, and the gate electrode 143 is separated from the semiconductor material layer 12 through the in-trench dielectric layer 133. The thickness of the in-trench dielectric layers 131, 132, 133 may be adjusted based on the size of the electrode 14 or the operating voltage. In an example, the thicknesses of the in-trench dielectric layers 131 and 132 may be approximately the same, and the thickness of the in-trench dielectric layer 133 is smaller than the thickness of the in-trench dielectric layer 131 or 132.

The vertical power semiconductor device 1 has a plurality of doped regions 21, 22, 23, 24 in addition to the lightly doped region 25.

The doped region 21, serving as the body doped region of the vertical power semiconductor device 1 (hereinafter generally referred to as the body doped region 21), is located in the semiconductor material layer 12 between the gate electrode 143 and the shield electrode 141 and between the gate electrode 143 and the shield electrode 142, and is close to the surface 12A. In some embodiments, the body doped region 21 is located above the lightly doped region 25 and adjoins the lightly doped region 25. The body doped region 21 has a conductivity type different from that of the lightly doped region 25, e.g., it is P type. The depth of the body doped region 21 is smaller than that of the gate electrode 143.

The doped region 22, serving as the source of the vertical power semiconductor device 1 (hereinafter generally referred to as the source doped region 22), is located in the body doped region 21 and close to the surface 12A of the semiconductor material layer 12. The depth of the source doped region 22 is smaller than the depth of the body doped region 21, and has a conductivity type different from that of the body doped region 21, e.g., N type. In some embodiments, the source doped region 22 adjoins the surface 12A of the semiconductor material layer 12. In some embodiments, the doping concentration of the source doped region 22 is greater than that of the body doped region 21. In some embodiments, the gate electrode 143 extends through the source doped region 22 along the vertical direction. In some embodiments, the source doped region 22 includes a source doped region 221 located between the gate electrode 143 and the shield electrode 141, and a source doped region 222 located between the gate electrode 143 and the shield electrode 142, as shown in FIG. 1.

The doped region 24 in the vertical power semiconductor device 1 is used as the doped region of the SBD (hereinafter generally referred to as the SBD doped region 24), and is located in the body doped region 21 and close to the lightly doped region 25. The SBD doped region 24 has a depth that is smaller than the depth of the body doped region 21, and has a conductivity type different from that of the body doped region 21, such as N type. In some embodiments, the SBD doped region 24 is close to the bottom of the body doped region 21 and separated from the surface 12A of the semiconductor material layer 12. In some embodiments, the SBD doped region 24 is separated from the source doped region 22. In some embodiments, the SBD doped region 24 is in contact with the lightly doped region 25. In some embodiments, the bottom of the SBD doped region 24 is located right at the bottom of the body doped region 21. In some embodiments, the SBD doped region 24 protrudes from the bottom of the body doped region 21, and part of the SBD doped region 24 is located in the lightly doped region 25. The doping concentration of the SBD doped region 24 is smaller than the doping concentration of the source doped region 22. In some embodiments, the doping concentration of the SBD doped region 24 is approximately equal to the doping concentration of the lightly doped region 25.

The SBD doped region 24 may include an SBD doped region 241 that is close to the shield electrode 141, and an SBD doped region 242 close the shield electrode 142. The SBD doped region 241 is separated from the gate electrode 143 through a portion of the body doped region 21, and the SBD doped region 242 is separated from the gate electrode 143 through another portion of the body doped region 21. In other words, the portion of the body doped region 21 is located between the gate electrode 143 and the SBD doped region 241, and another portion of the body doped region 21 is located between the gate electrode 143 and the SBD doped region 242. In some embodiments, the width of the SBD doped region 241 is smaller than the width of the source doped region 22. For the convenience of description, the widths of components in the present disclosure are measured in the horizontal direction.

The doped region 23 may be located in the body doped region 21 and serve as a heavily doped region in the body doped region 21 (hereinafter generally referred to as the heavily doped region 23). The heavily doped region 23 may have a conductivity type different from that of the body doped region 21, such as N type. In some embodiments, the doping concentration of the heavily doped region 23 is smaller than the doping concentration of the source doped region 22 and greater than the doping concentration of the SBD doped region 24. In some embodiments, the doping concentration of the heavily doped region 23 is less than that of the source doped region 22 and greater than that of the body doped region 21. In some embodiments, the heavily doped region 23 is located between the source doped region 22 and the SBD doped region 24, and is separated from the surface 12A of the semiconductor material layer 12. In some embodiments, the heavily doped region 23 is in contact with the bottom of the source doped region 22 and the top of the SBD doped region 24. In some embodiments, the width of the heavily doped region 23 is smaller than the width of the source doped region 22. In some embodiments, the width of the heavily doped region 23 is greater than or equal to the width of the SBD doped region 24.

The heavily doped region 23 may include a heavily doped region 231 close to the shield electrode 141, a heavily doped region 232 close to the shield electrode 142, a heavily doped region 233 located in the shield electrode 141, and a heavily doped region 234 located in the shield electrode 142. The heavily doped region 231 is separated from the gate electrode 143 by a portion of the body doped region 21, and the heavily doped region 232 is separated from the gate electrode 143 by another portion of the body doped region 21. In other words, the portion of the body doped region 21 is located between the gate electrode 143 and the heavily doped region 231, and another portion of the body doped region 21 is located between the gate electrode 143 and the heavily doped region 232. The heavily doped regions 233 and 234 are located respectively in the shield electrodes 141 and 142, and surround the conductive plugs 16 disposed in the shield electrodes 141 and 142.

The conductive plugs 16 may extend from above the surface 12A of the semiconductor material layer 12 toward the surface 12B in the vertical direction, and connect the shield electrode 14 to the source doped region 22, the heavily doped region 23, and the SBD doped region 24 in the semiconductor material layer 12. The conductive plugs 161 and 162 are located above the shield electrode 14, and are respectively connected to different shield electrodes 14, such as the shield electrodes 141 and 142. The conductive plug 163 is located between the shield electrode 141 and the gate electrode 143, and is close to the shield electrode 141 and separated from the shield electrode 141. The conductive plug 163 extends through the source doped region 221 and the heavily doped region 231, contacts the SBD doped region 241, and is separated from the first type doped region 25. In some embodiments, the SBD doped region 241 surrounds the bottom of the conductive plug 163. The conductive plug 164 is provided opposite to the conductive plug 163, The conductive plug 164 is located between the shield electrode 142 and the gate electrode 143, close to the shield electrode 142 and separated from the shield electrode 142. The conductive plug 164 extends through the source doped region 222 and the heavily doped region 232, and contacts the SBD doped region 242, and is separated from the lightly doped region 25. In some embodiments, the SBD doped region 242 surrounds the bottom of conductive plug 164. In some embodiments, the conductive plugs 16 may include conductive plugs other than the conductive plugs 161, 162, 163, 164 shown in the figures, in order to electrically connect to the gate electrode 143.

The configuration of each conductive plug 16 may vary depending on the process or electrical requirements. For example, the conductive plugs 161, 162 may both be in a columnar shape. For example, the conductive plugs 163 and 164 may have a configuration that is wide at the top and narrow at the bottom, as shown in the cross-sectional view of FIG. 1. In some embodiments, the conductive plugs 161 and 162 may have approximately the same width along the vertical direction. In some embodiments, the width of the electrical plug 163 or 164 at the surface 12A of the semiconductor material layer 12 is greater than the width of the electrical plug 163 or 164 in the SBD doped region 24. In some embodiments, the width of the conductive plug 163 or 164 in the heavily doped region 23 has a width that decreases along the vertical direction from the surface 12A toward the surface 12B. In some embodiments, the conductive plug 163 or 164 has a first sidewall close to the gate electrode 143, and a second sidewall opposite to the first sidewall, where the second sidewall is close to the shield electrode 141 or 142. The second sidewall is connected to the bottom of the conductive plug 163 or 164, and the first sidewall ends between the surface 12A and the bottom of the conductive plug 163 or 164.

In some embodiments, the vertical power semiconductor device 1 may further include a drain contact region 11, an interlayer dielectric layer 15, a metal layer 17.

The drain contact region 11 is located on the surface 12B, for contacting a drain metal layer (not shown, which may be formed on a surface 11B to be in contact with the drain contact region 11, and formed as a metal layer that functions as a drain). The drain contact region 11 has doping of the same conductivity type as the lightly doped region 25. The drain contact region 11 may be disposed on an upper surface close to a silicon wafer or a substrate of other semiconductor material. In some embodiments, the drain contact region 11 may be part of the silicon wafer or the substrate. The material of the drain contact region 11 may be, e.g., single crystal silicon material, epitaxial silicon material, silicon carbide (SiC), germanium (Ge), silicon germanium (SiGe), gallium nitride (GaN), gallium arsenide (GaAs), gallium arsenide phosphorus (GaAsP), or other semiconductor materials. In some embodiments, the doping concentration of the drain contact region 11 may be greater than that of the lightly doped region 25.

The interlayer dielectric layer 15 is located on the surface 12A of the semiconductor material layer 12, to separate the metal layer 17 on the interlayer dielectric layer 15 and the semiconductor material layer 12. In some embodiments, the conductive plugs 16 extend through the interlayer dielectric layer 15 to electrically connect to the electrode 14 and the doped regions 21, 22, 23, 24, respectively. In some embodiments, the metal layer 17 may be a metal wire layer in a pattern and is used to adjust electrical paths according to actual operation requirements, including multiple metal wires electrically connected to different electrodes 14 or the doped regions 21, 22, 23, 24. In some embodiments, the metal layer 17 may be a first metal layer (M1) of an interconnect structure.

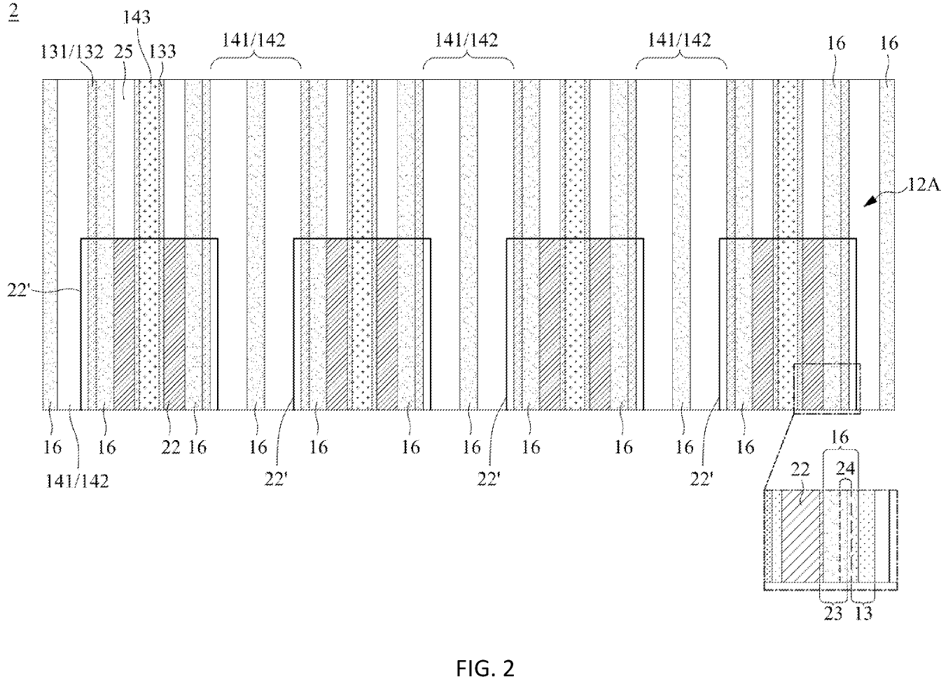

FIG. 2 is a top view of a vertical power semiconductor device 2 according to some embodiments of the present disclosure. The vertical power semiconductor device 2 includes a plurality of vertical power semiconductor devices 1 arranged side by side. FIG. 2 is a top view viewed from the surface 12A of the semiconductor material layer 12. The electrodes 14 (e.g., the shield electrodes 141, 142, the gate electrode 143) extend in the same direction and are parallel to each other. In some embodiments, the source doped region 22 only overlaps a portion of the electrode 14. In some embodiments, each electrode 14 has a portion extending beyond the coverage of the source doped region 2. In some embodiments, the heavily doped region 23 and the SBD doped region 24 are covered by the source doped region 22, and are therefore not visible from the top view in FIG. 2. It is worth noting that during the ion distribution process in the source doped region 22, in order to ensure that the source doping region 22 completely covers the space between the shield electrode 141 and the gate electrode 143 and the space between the shield electrode 142 and the gate electrode 143, the ion distribution process may have a coverage range as shown by the block 22′ in FIG. 2. But the source doped region 22 may only be formed in the semiconductor material layer 12.

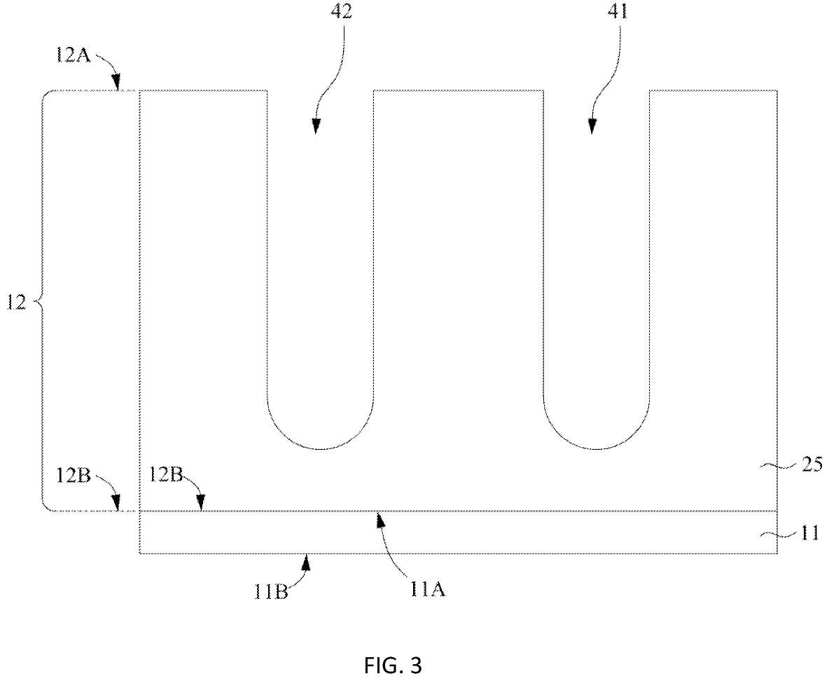

FIG. 3 to FIG. 16 are diagrams showing one or more stages in a manufacturing method of a vertical power semiconductor device according to some embodiments of the present disclosure. At least some of these figures have been simplified for the purpose of better understanding the aspects of the present disclosure.

Referring to FIG. 3, the manufacturing method includes performing epitaxial growth on a surface 11A of the drain contact region 11 to form the semiconductor material layer 12. The drain contact region 11 may be located on a top surface close to a substrate or a silicon wafer, and have the surface 11A and the surface 11B opposite to the surface 11A. In some embodiments, the surface 11A may be the top surface of the substrate or the silicon wafer. In some embodiments, the surface 11B of the drain contact region 11 is located in the substrate or silicon wafer. In some embodiments, ions having N-type electrical properties may be implanted during the epitaxial growth to form an N-type semiconductor material layer 12, and the lightly doped region 25 may be formed without the need of additional ion implantation. Trenches 41 and 42 may respectively extend from the surface 11A toward the surface 11B. The trenches 41, 42 may have vertical sidewalls. The trenches 41 and 42 may have arc-shaped bottom surfaces. In addition, the trenches 41, 42 may be circular, oval, rectangular or polygonal. The trenches 41 and 42 may be formed through an etching process (such as a plasma dry etching process) after the positions and patterns are defined through photoresist.

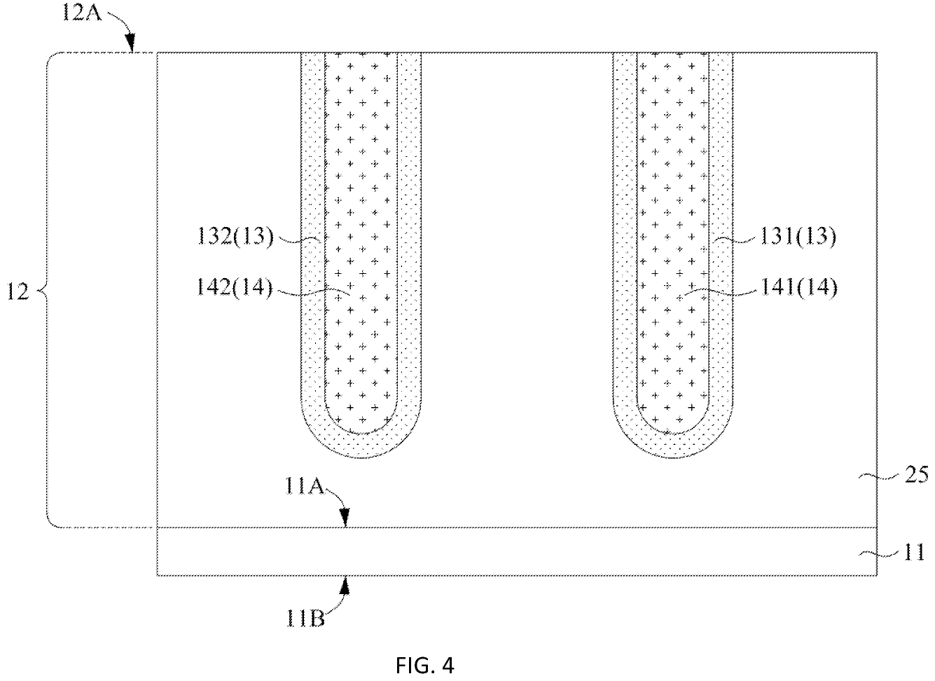

Referring to FIG. 4, the manufacturing method includes forming the in-trench dielectric layers 131, 132 and the shield electrodes 141, 142 in the trenches 41, 42. In some embodiments, the in-trench dielectric layers 131 and 132 may be formed by atomic layer deposition (ALD), chemical vapor deposition (CVD), or other deposition processes. In some embodiments, the in-trench dielectric layers 131 and 132 may be formed through thermal oxidation technology. In some embodiments, the in-trench dielectric layer 131, 132 may be deposited conformally on the inner surfaces of the trenches 41, 42 (including the opposite sidewalls and the bottom extending between the sidewalls). In some embodiments, the in-trench dielectric layers 131 and 132 may be filled into the trenches 41 and 42 through a deposition process, and then a lithography and etching process is performed to partially remove the in-trench dielectric layers 131 and 132, to form at least one groove in the in-trench dielectric layers 131 and 132. In some embodiments, the in-trench dielectric layers 131, 132 may cover the surface 12A, and then the in-trench dielectric layer 13 that is outside of the trenches 41 and 42 may be grinded and removed by using a grinding process, e.g., a chemical mechanical polishing (CMP) process. In some embodiments, the upper surfaces of the in-trench dielectric layers 131, 132 are flush with the surface 12A.

Next, the shield electrodes 141 and 142 are formed in the trenches 41 and 42. The in-trench dielectric layer 13 may surround the shield electrodes 141, 142. In some embodiments, the shield electrodes 141 and 142 may be formed by physical vapor deposition (PVD), such as sputtering or spraying. In some embodiments, the shield electrodes 141, 142 may be formed by electroplating or CVD. In some embodiments, electrode material may cover the surface 12A, and then the electrode material outside of the trenches 41 and 42 may be grinded and removed by a grinding process, e.g., the chemical mechanical polishing (CMP) process, to form the shield electrodes 141 and 142. In some embodiments, the electrode material includes polysilicon. In some embodiments, the upper surfaces of the shield electrode 141, 142 are flush with the surface 12A. For the convenience of description, the shield electrode 141 and the in-trench dielectric layer 131 may be collectively referred to as a shield electrode structure. Similarly, the shield electrode 142 and the in-trench dielectric layer 132 may also be referred to as another shield electrode structure.

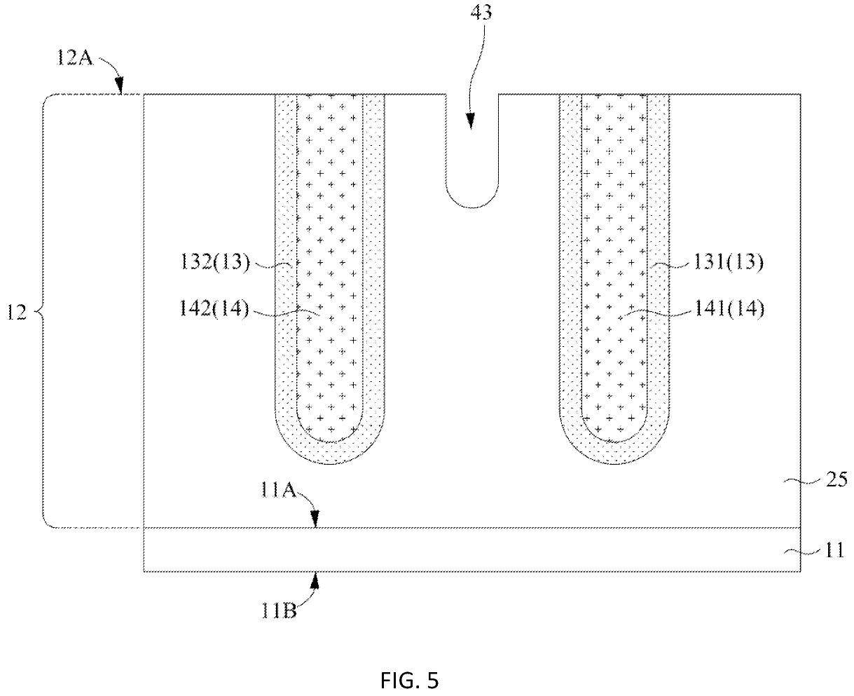

Referring to FIG. 5, the manufacturing method includes forming a trench 43 in the semiconductor material layer 12 between the shield electrodes 141 and 142 (or between the shield electrode structures). For the formation method of the trench 43, please refer to the formation method of the trenches 41 and 42, which will not be repeated herein. The depth of the trench 43 may be smaller than the depth of the trench 41 or 42. The width of the trench 43 may be smaller than the width of the trench 41 or 42.

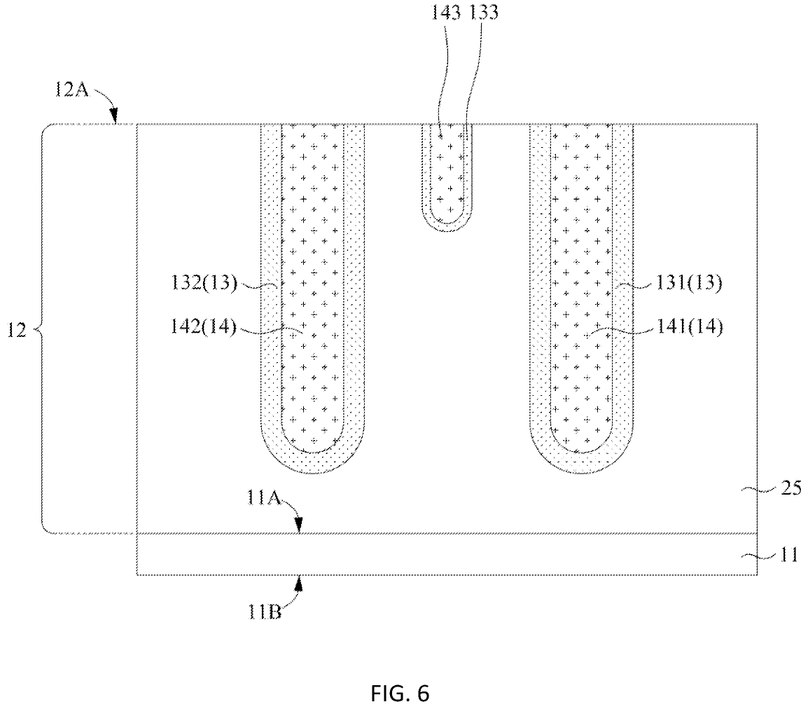

Referring to FIG. 6, the manufacturing method includes forming an in-trench dielectric layer 133 and a gate electrode 143 in the trench 43. For the formation method of the in-trench dielectric layer 133 and the gate electrode 143, please refer to the formation method of the in-trench dielectric layers 131 and 132 and the shield electrodes 141 and 142, which will not be repeated. The thickness of the in-trench dielectric layer 133 may be smaller than that of the in-trench dielectric layer 131 or 132. In some embodiments, the upper surface of the gate electrode 143 may be flush with the surface 12A. For the convenience of description, the gate electrode 143 and the in-trench dielectric layer 133 may be collectively referred to as a gate electrode structure, and the gate electrode structure and the shield electrode structures may be collectively referred to as an electrode structure.

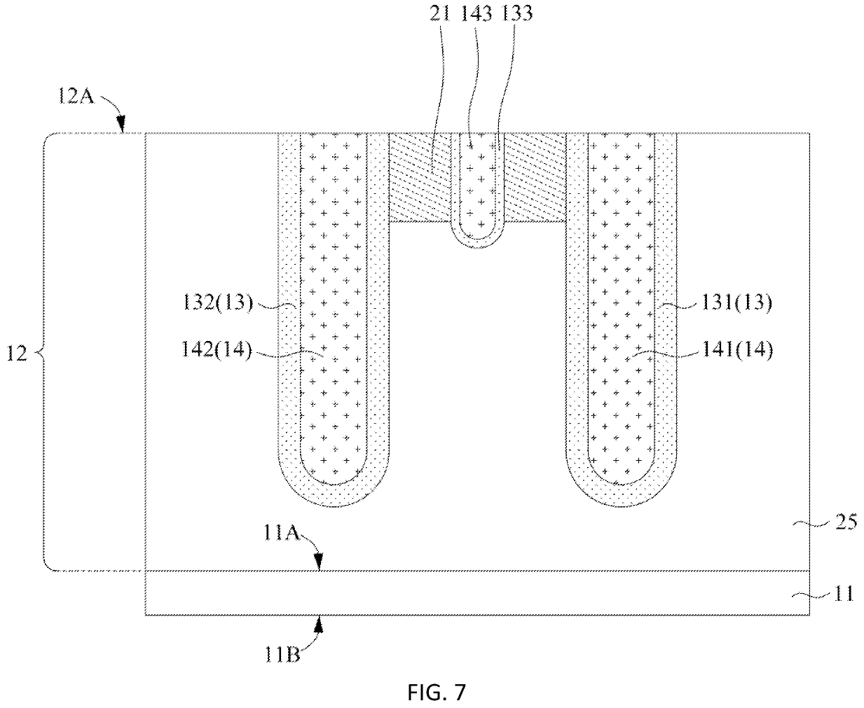

Referring to FIG. 7, the manufacturing method includes forming the body doped region 21 in the semiconductor material layer 12 between the electrode structures. The body doped region 21 may be a second type doped region formed through a diffusion or ion implantation process from the surface 12A. The depth of the body doped region 21 may be smaller than the depth of the gate electrode structure. In other words, the bottom of the body doped region 21 may be higher than the bottom of the gate electrode structure. In addition, since the body doped region 21 offsets the conductivity of the lightly doped region 25, in terms of electrical property, the coverage of the lightly conductive region 25 may be defined as a portion of the semiconductor material layer 12 that is outside of the body doped region 21. In some embodiments, an annealing process may be performed after the ion implantation process in order to diffuse the doping ions.

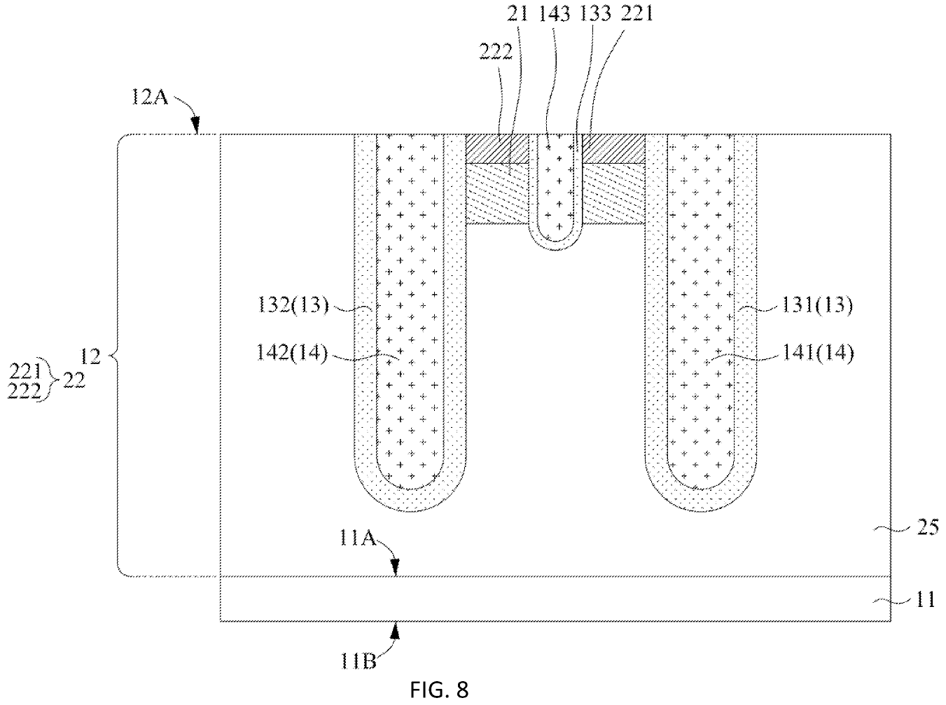

Referring to FIG. 8, the manufacturing method includes forming the source doped region 22 in the body doped region 21 between the electrode structures. The source doped region 22 may be a first type doped region formed through a diffusion or ion implantation process from the surface 12A. The doping concentration of the source doped region 22 is greater than that of the body doped region 21. The depth of the source doped region 22 is less than the depth of the body doped region 21. The source doped region 22 may be distributed on both sides of the gate electrode structure, e.g., the source doped region 221 close to the shield electrode 141 and the source doped region 222 close to the shield electrode 142. In order to ensure that the source doped region 22 covers the region between the electrode structures, the area for the ion implantation process may be defined as the area of the block 22′ shown in the top view of FIG. 2. The source doped region 22 may cover a small portion of the shield electrodes 141 and 142, which, however, does not affect the usage. For the sake of simplicity of the drawings, FIGS. 3 to 16 show that the source doped region 22 is only formed on the electrode structure. In some embodiments, a patterned mask layer (hereinafter generally referred to as a first mask layer) may be formed on the semiconductor material layer 12 to define the position of the source doped region 22. The conductivity type and depth of the source doped region 22 may be defined by adjusting the ions implanted, the energy and the amount in the diffusion or ion implantation process. In some embodiments, the first mask layer may be formed by performing a photolithography process using a photomask with a corresponding pattern (hereinafter generally referred to as a first photomask). In some embodiments, an annealing process may be performed each time after the ion implantation process is performed, in order to diffuse the doping ions.

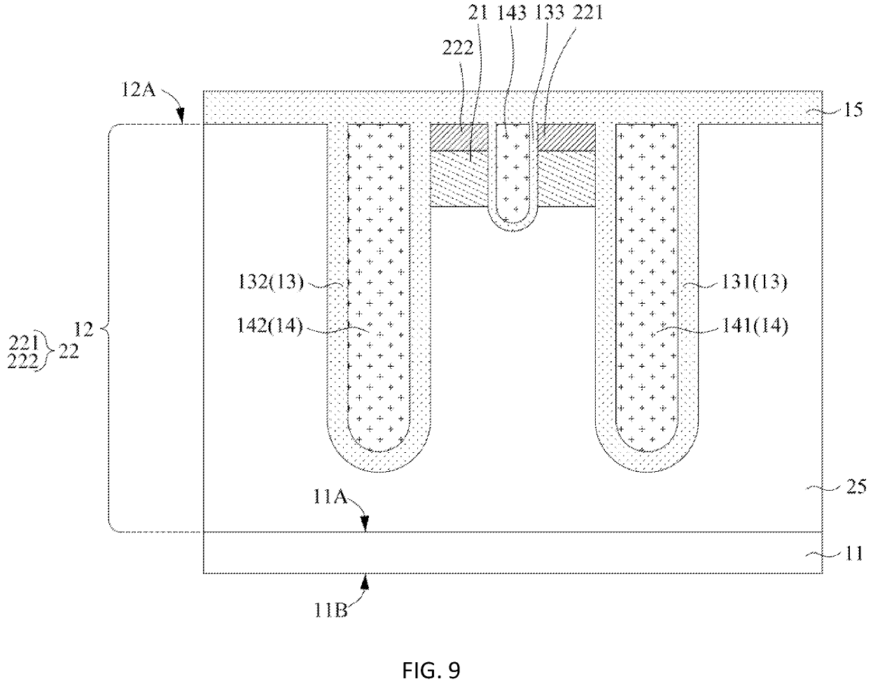

Referring to FIG. 9, the manufacturing method includes forming the interlayer dielectric layer 15 on the surface 12A of the semiconductor material layer 12. The interlayer dielectric layer 15 may be formed by ALD, CVD or other deposition processes.

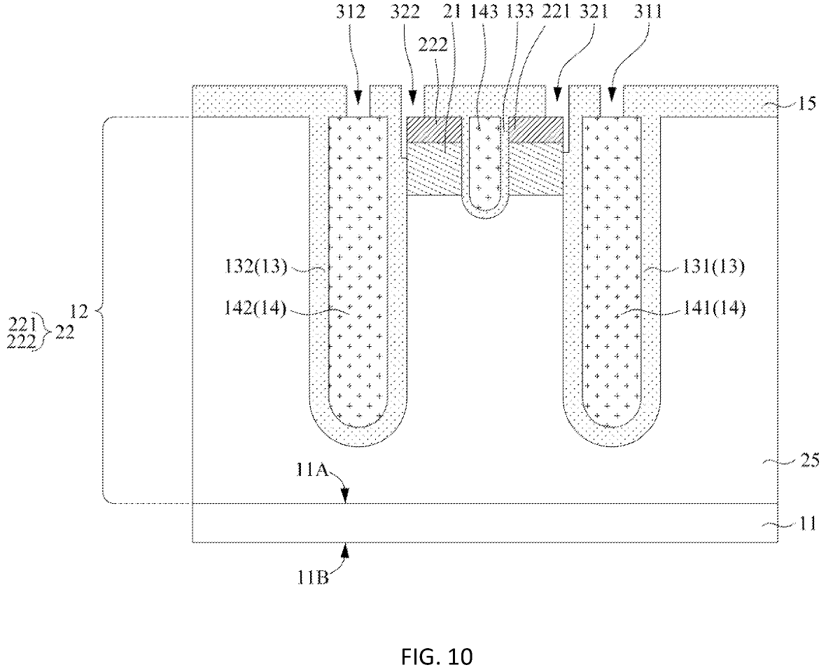

Referring to FIG. 10, the manufacturing method includes partially removing the interlayer dielectric layer 15 to form openings 311, 312, 321, 322. The openings 311 and 312 expose the shield electrodes 141 and 142, and the openings 321 and 322 expose a portion of the semiconductor material layer 12 that is close to the shield electrodes 141 and 142. In some embodiments, a patterned mask layer (hereinafter generally referred to as a second mask layer) may be formed on the interlayer dielectric layer 15. The positions of the openings 311, 312, 321, and 322 may be defined by the second mask layer, and the openings 311, 312, 321, and 322 may be formed by a dry etching process. The dry etching process removes dielectric materials until reaching the semiconductor material layer 12 or the shield electrodes 141, 142. Based on the positions defined by the second mask layer, the openings 321 and 322 may cover a portion of the in-trench dielectric layers 131 and 132 that is close to the semiconductor material layer 12. In some embodiments, the dry etching process may be used to remove a portion of the in-trench dielectric layers 131 and 132 that adjoins the semiconductor material layer 12, so that a portion of the semiconductor material layer 12 that is in contact with the sidewalls of the in-trench dielectric layers 131 and 132 is exposed by the openings 321, 322. In some embodiments, the opening 321 or 322 may extend downward below the surface 12A, and the width of the opening 321 or 322 below the surface 12A is smaller than the width of the opening 321 or 322 above the surface 12A. In the embodiment, the opening 321 or 322 may extend below the source doped region 22. In some embodiments, the second mask layer may be formed by performing a photolithography process using a photomask with a corresponding pattern (hereinafter generally referred to as a second photomask, which has a different pattern than the first photomask).

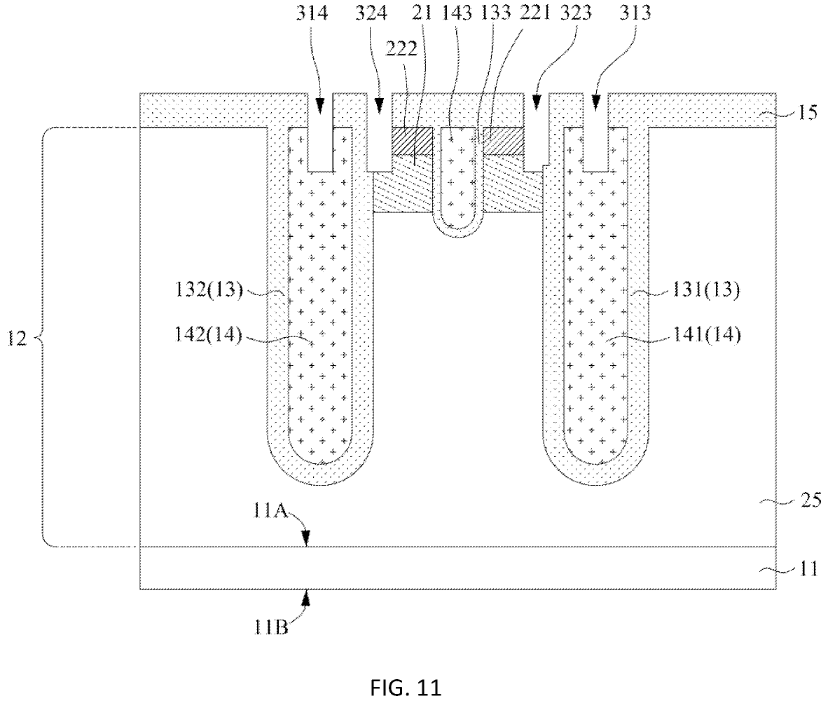

Referring to FIG. 11, the manufacturing method includes using the interlayer dielectric layer 15 as a mask to partially remove the shield electrodes 141 and 142 and the semiconductor material layer 12. In some embodiments, a dry etching process may be performed on the exposed semiconductor material layer 12 and shield electrodes 141 and 142, utilizing the interlayer dielectric layer 15 as a mask. For the convenience of description, the openings 311, 312, 321, 322 are herein redefined as openings 313, 314, 323, 324. In some embodiments, the openings 323, 324 pass through the source doped region 22 and end in the body doped region 21 that is below the source doped region 22. In some embodiments, the bottom of the opening 323 or 324 may be higher than, lower than, or approximately equal to the horizontal level of the bottom of the opening 321 or 322 in FIG. 10. In some embodiments, the depths of the openings 313, 314 may be greater than the depths of the openings 323, 324. In some embodiments, the depths of the openings 313, 314 may be approximately equal to the depths of the openings 323, 324.

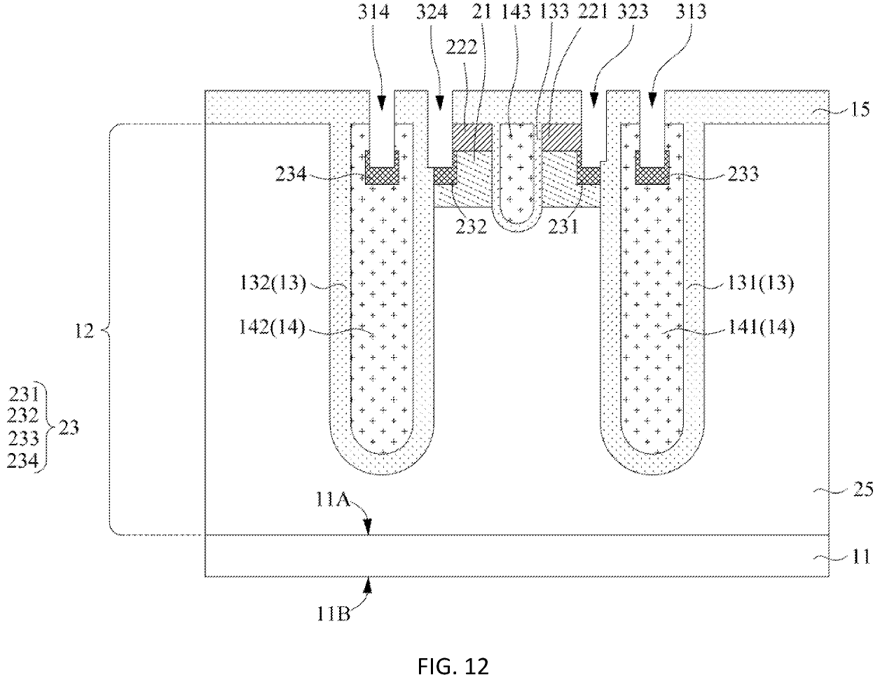

Referring to FIG. 12, the manufacturing method includes performing an ion implantation process to the semiconductor material layer 12 and the electrodes 141 and 142 based on the openings 313, 314, 323, and 324, to form the heavily doped regions 231, 232, 233, and 234. Ions may be implanted in the vertical direction into the semiconductor material layer 12 and the shield electrodes 141, 142 at the bottom of the openings 313, 314, 323, 324. The heavily doped region 231, 232 may be formed respectively in the semiconductor material layer 12 that is close to the bottoms of the openings 323 and 324, and the heavily doped regions 233 and 234 are formed respectively in the shield electrodes 141, 142 that are close to the bottoms of the openings 313, 314. In some embodiments, an annealing process may be performed after the ion implantation process to form the heavily doped regions 231, 232, 233, and 234 shown in FIG. 12.

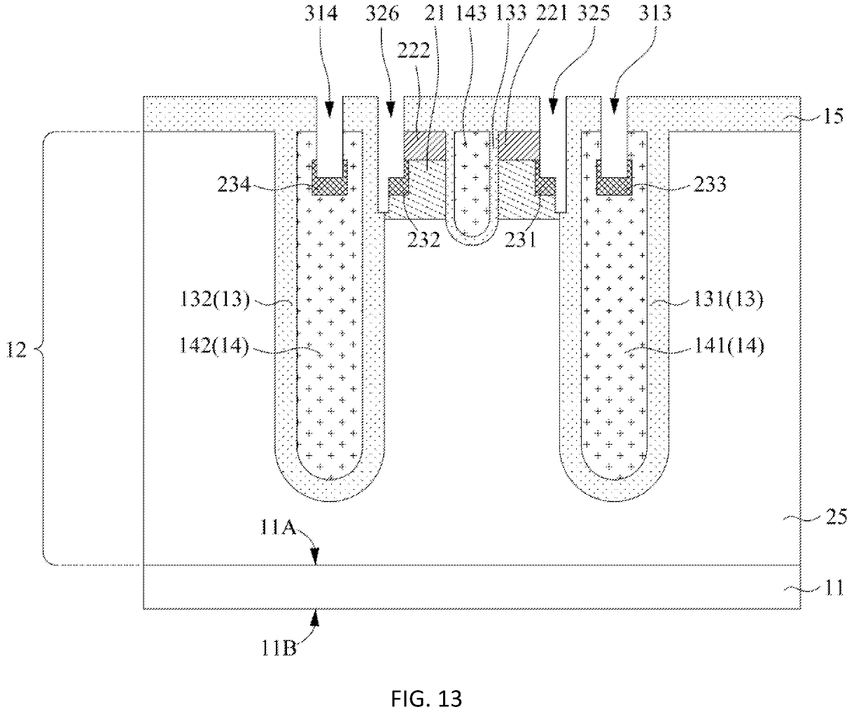

Referring to FIG. 13, the manufacturing method includes partially removing the in-trench dielectric layers 131, 132 according to the openings 323, 324. The removal steps shown in FIG. 13 are similar to those shown in FIG. 10, but using a different patterned mask layer (hereinafter generally referred to as a third mask layer). The in-trench dielectric layers 131 and 132 below the openings 323 and 324 are exposed. A dry etching process is performed to partially remove the in-trench dielectric layers 131, 132 along the sidewalls of the semiconductor material layer 12. In some embodiments, the dry etching process may be used to remove a portion of the in-trench dielectric layers 131, 132 that adjoins the heavily doped region 23 and adjoins the body doped region 21 below the heavily doped region 23. In some embodiments, the plasma impact of the dry etching process causes removal of a part of the sidewalls of the semiconductor material layer 12. For the convenience of description, the openings 323 and 324 are herein redefined as openings 325 and 326. In some embodiments, the dry etching process may be controlled so that the openings 325 and 326 end above the lightly doped region 25 and are separated from the lightly doped region 25. In some embodiments, the third mask layer covers the openings 313, 314.

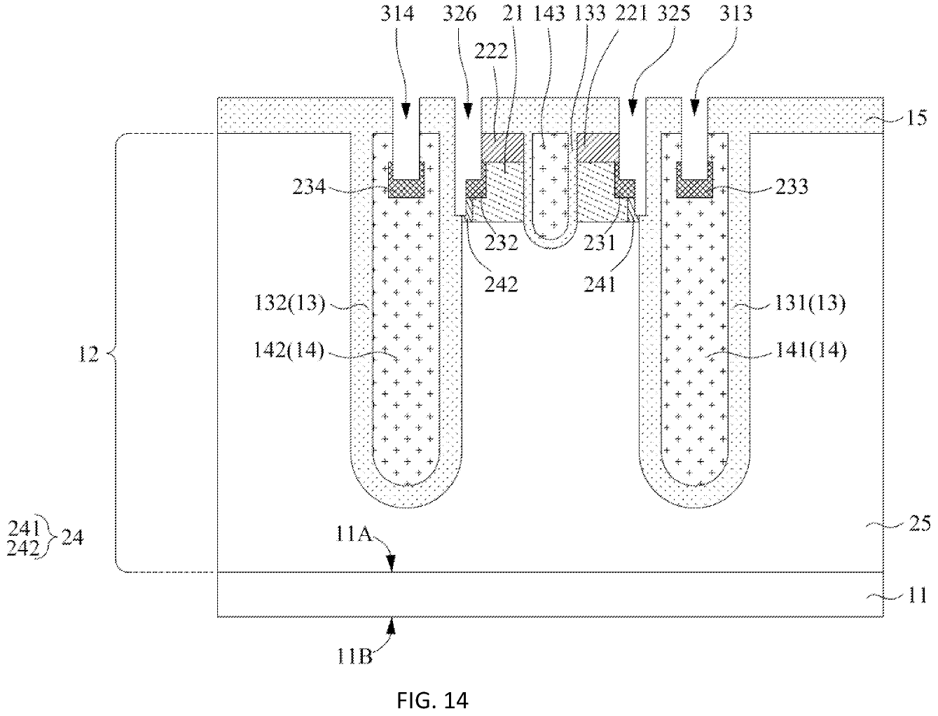

Referring to FIG. 14, the manufacturing method includes performing an ion implantation process on the semiconductor material layer 12 according to the openings 325, 326, to form the SBD doped region 24. In some embodiments, to prevent ions from being implanted into the shield electrodes 141, 142, the third mask layer may be removed after the ion implantation process in FIG. 14 is performed (after the SBD doped region 24 is formed). The ion implantation process in FIG. 14 may be similar to the ion implantation process described with respect to FIG. 12. The ions are implanted in the vertical direction into the semiconductor material layer 12 at the bottom of the openings 325 and 326. The SBD doped regions 241 and 242 are respectively formed in the semiconductor material layer 12 that is close to the bottoms of the openings 325 and 326.

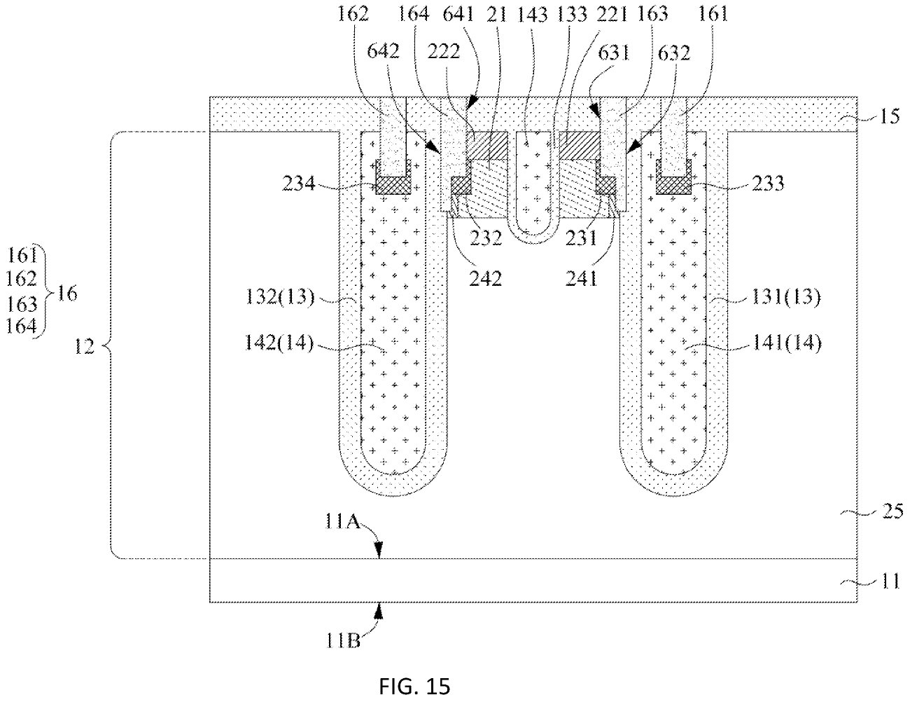

Referring to FIG. 15, the manufacturing method includes forming the conductive plugs 16 in the openings 325, 326, 313, and 314. The conductive plugs 16 may be formed by filling the openings 325, 326, 313, 314 with conductive material through electroplating or CVD. Materials of the conductive plugs 16 may include gold (Au), silver (Ag), copper (Cu), platinum (Pt), palladium (Pd), tungsten (W), titanium (Ti), tantalum (Ta), molybdenum (Mo) or other metals or alloys.

The configurations/shapes of the conductive plugs 16 may be defined by the configurations/shapes of the openings 325, 326, 313, 314, and thus have the same configurations/shapes as the openings 325, 326, 313, 314. In some embodiments, the width of the conductive plug 161 at the surface 12A may be approximately the same as that of the bottom of the conductive plug 161. In some embodiments, the conductive plug 162 has a configuration/shape similar or identical to the conductive plug 161. In some embodiments, the conductive plug 163 has sidewalls 631, 632 opposite to each other, where the sidewall 631 is closer to the gate electrode 143 than the sidewall 632, and the sidewalls 631 and 632 have different lengths along the vertical direction. In some embodiments, the sidewall 632 is connected to the bottom of the conductive plug 163, and the sidewall 631 ends between the surface 12A and the bottom of the conductive plug 163. In some embodiments, the sidewall 631 ends in the heavily doped region 231. In some embodiments, the conductive plug 164 has sidewalls 641, 642 opposite to each other, where the sidewall 641 is closer to the gate electrode 143 than the sidewall 642, and the sidewalls 641, 642 have different lengths along the vertical direction. In some embodiments, the sidewall 642 is connected to the bottom of the conductive plug 164, and the sidewall 641 ends between the surface 12A and the bottom of the conductive plug 164. In some embodiments, the sidewall 641 ends in the heavily doped region 232.

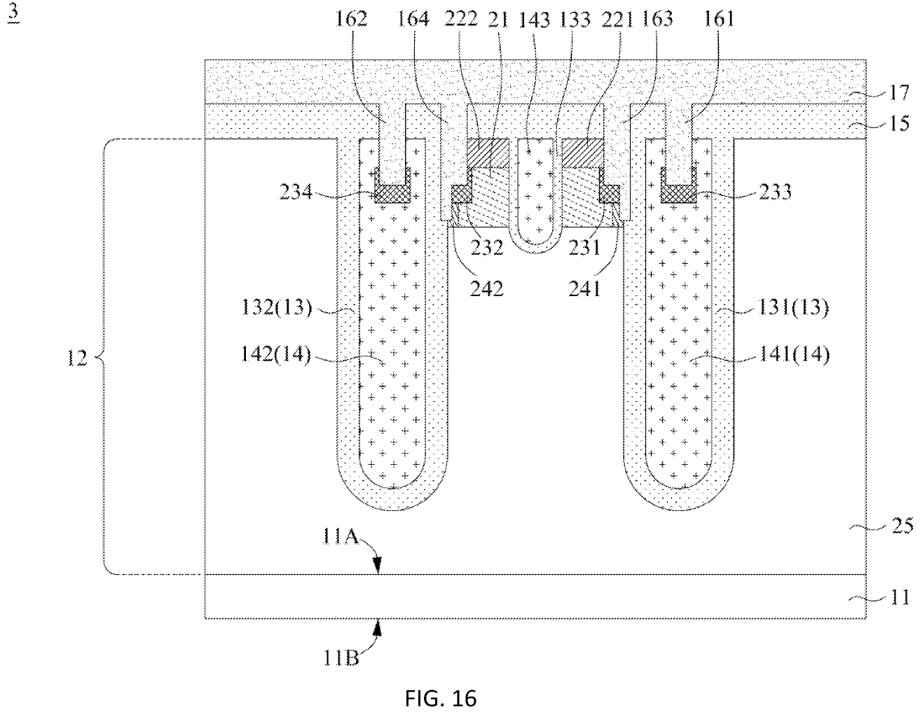

Referring to FIG. 16, the manufacturing method includes forming a metal layer 17 on the interlayer dielectric layer 15. The metal layer 17 may be formed by electroplating or CVD, and may be provided with patterns according to the electrical properties and operation requirements. The material of the metal layer 17 may include copper (Cu), gold (Au), silver (Ag), aluminum (Al), nickel (Ni), titanium (Ti), tungsten (W), tin (Sn) or other metals or alloys.

The vertical power semiconductor device 3 formed through the above steps may be similar to the vertical power semiconductor device 1 described with respect to FIG. 1. The vertical power semiconductor device 3 has the SBD doped region 24 placed in the body doped region 21, and source contact plugs (e.g., the conductive plugs 163, 164) may be used as the metal of the SBD, which integrates the SBD process with the general process for vertical power semiconductors, and achieves the effect of reducing the process costs and reducing the total surface area of the device.

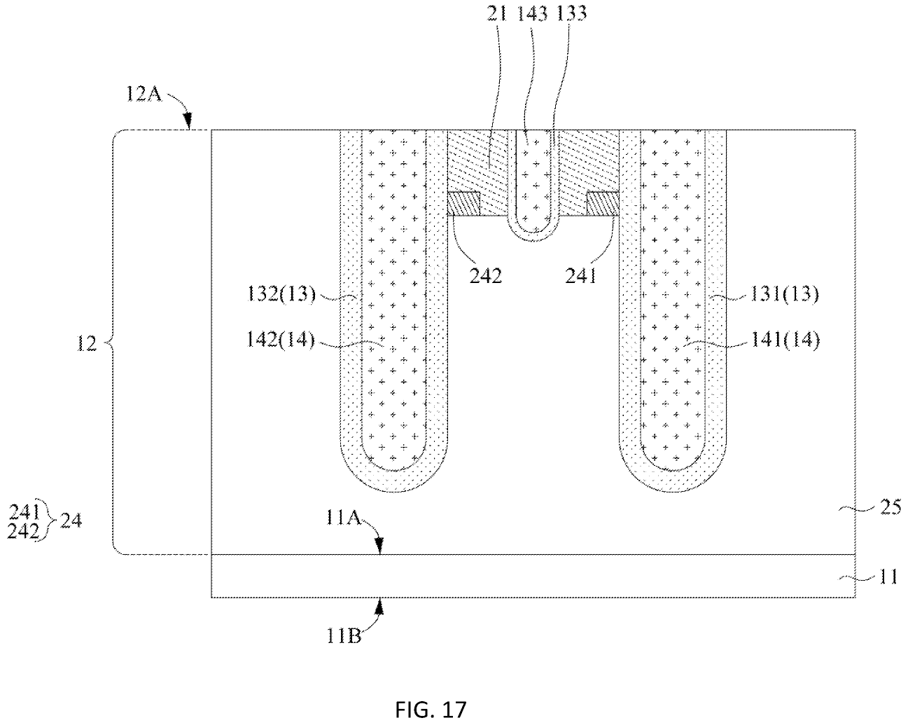

According to the structures and processes of the embodiments of the present disclosure described above, and with the same purpose and concept, the steps in the above processes may be adjusted, or the order of the steps may be changed in order to achieve the same or similar vertical power semiconductor devices. FIG. 17 to FIG. 23 show one or more stages in an example manufacturing method of a vertical power semiconductor device according to other embodiments of the present disclosure. At least some of the figures have been simplified to provide a better understanding of aspects of the present disclosure. For the convenience of description, the manufacturing method described with respect to FIG. 3 to FIG. 16 is generally referred to as a first manufacturing method, and the manufacturing method described with respect to FIG. 17 to FIG. 23 is generally referred to as a second manufacturing method. Different from the first manufacturing method in which the openings are first formed and then doping is performed, in the second manufacturing method, the doped regions 23 and 24 are first formed, and then openings of the interlayer dielectric layer 15 are formed.

Referring to FIG. 17, after the step as described with respect to FIG. 7 is performed (i.e., after the steps of FIG. 3-FIG. 7 are performed), the second manufacturing method includes forming the SBD doped region 24 in the body doped region 21 close to the shield electrode structures. The step in FIG. 17 may be performed with reference to the process described with respect to FIG. 8, however, a different patterned mask layer (generally referred to as a fourth mask layer) may be used to define the position of the SBD doped region 24. By adjusting the ions, the energy and the dose introduced through the diffusion or ion implantation process, the SBD doped region 24 can be controlled to be formed in the bottom region of the body doped region 21.

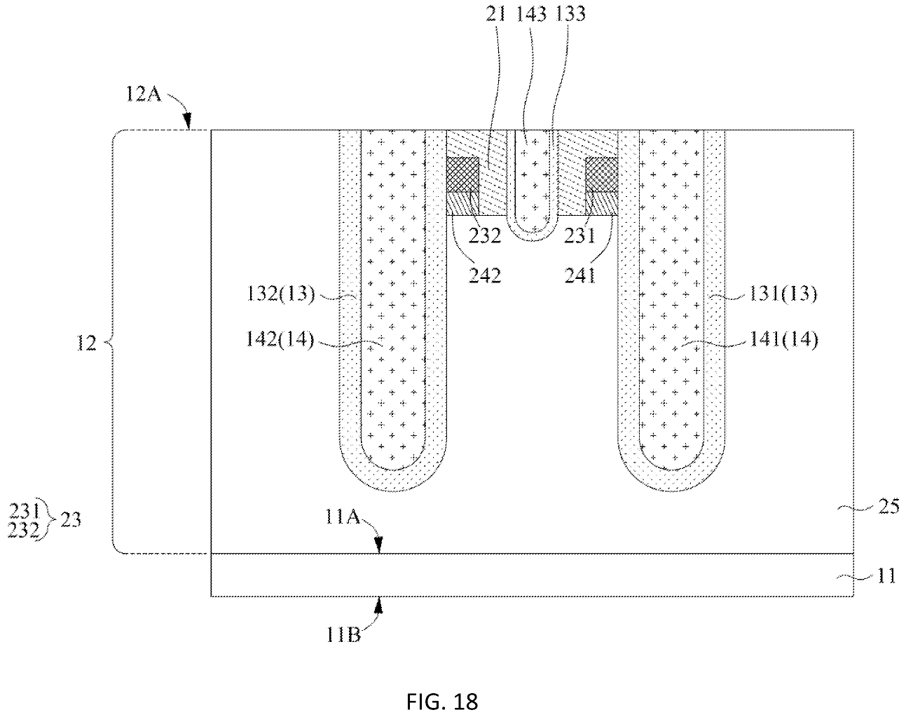

Referring to FIG. 18, the second manufacturing method includes forming the heavily doped region 23 in the body doped region 21 above the SBD doped region 24. The step of forming the heavily doped region 23 in FIG. 18 is similar to the step as described with respect to FIG. 17. The conductivity type and depth of the heavily doped region 23 can be controlled by adjusting the ions, energy and dose introduced through the ion implantation process. In some embodiments, the position of the heavily doped region 23 may be defined using the same fourth mask layer as in FIG. 17.

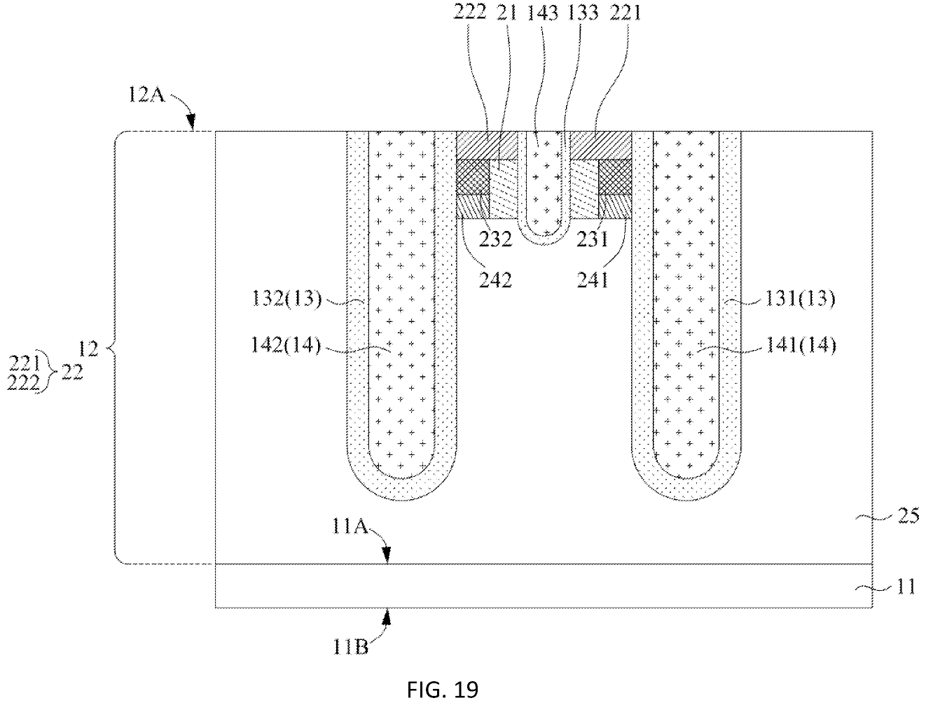

Referring to FIG. 19, the second manufacturing method includes forming the source doped region 22 in the body doped region 21 between the electrode structures and above the heavily doped region 23. The step in FIG. 19 may be performed with reference to the process described with respect to FIG. 8. In some embodiments, the step in FIG. 19 may include using the first photomask the same as that in the step of FIG. 8 to form a mask layer that has the same pattern as the first mask layer, to define the position of the source doped region 22.

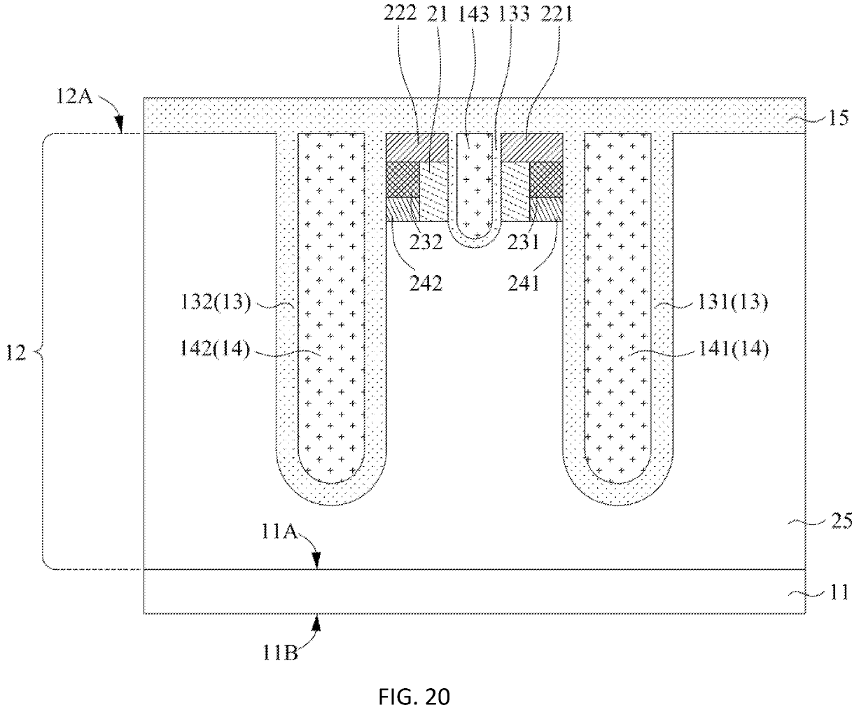

Referring to FIG. 20, the second manufacturing method includes forming the interlayer dielectric layer 15 on the surface 12A of the semiconductor material layer 12. The interlayer dielectric layer 15 can be formed through ALD, CVD or other deposition processes.

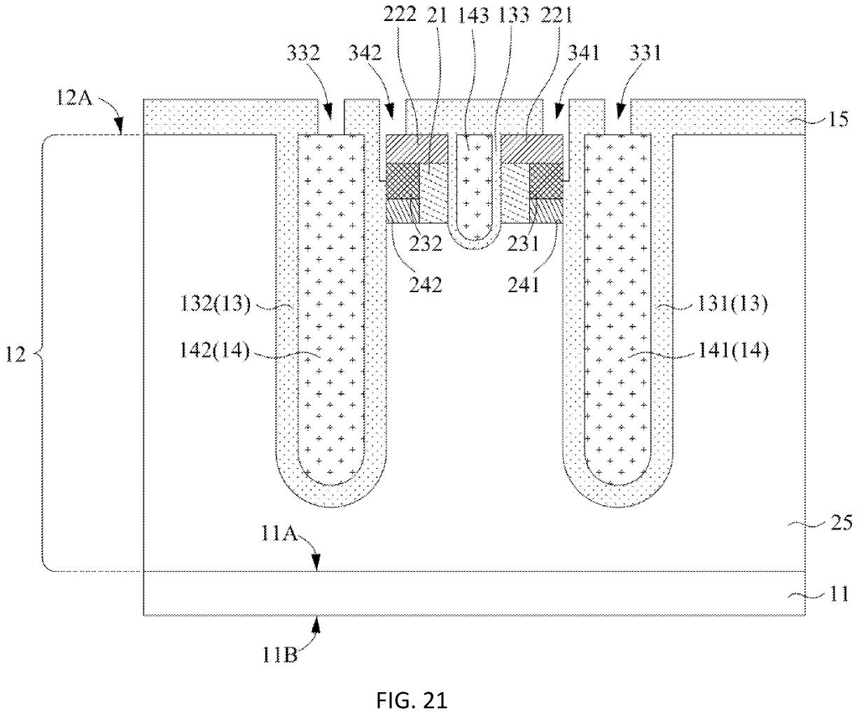

Referring to FIG. 21, the second manufacturing method includes partially removing the interlayer dielectric layer 15 to form the openings 331, 332, 341, 342. The openings 331 and 332 expose the shield electrodes 141 and 142, and the openings 341 and 342 expose a portion of the semiconductor material layer 12 that is close to the shield electrodes 141 and 142. For the step of FIG. 21, please refer to the description of the step described with respect to FIG. 10. In some embodiments, the step of FIG. 21 may include using a patterned mask layer having the same pattern as that in the step of FIG. 10 to define the positions of the openings 331, 332, 341, 342. In some embodiments, the photomask used in the step of FIG. 21 may be the same as the second photomask used in the step of FIG. 10.

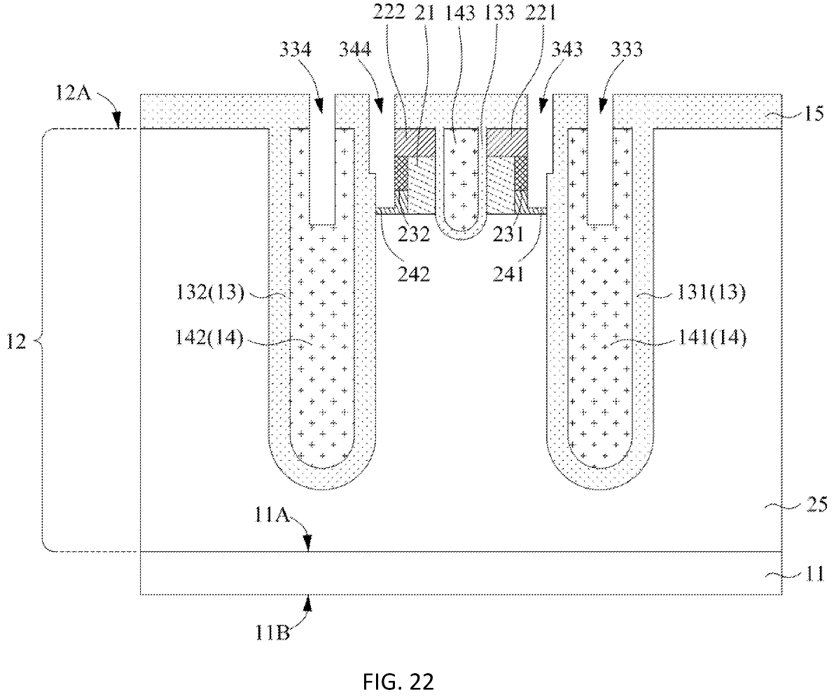

Referring to FIG. 22, the second manufacturing method includes using the interlayer dielectric layer 15 as a mask to partially remove the shield electrodes 141, 142 and the semiconductor material layer 12. For the convenience of description, the openings 331, 332, 341, 342 are herein redefined as the openings 333, 334, 343, 344. The openings 343 and 344 respectively end in the SBD doped regions 241 and 242, and are separated from the lightly doped region 25. In some embodiments, under the same etching conditions (e.g., energy, dose, time), the etching rate of the shield electrodes 141, 142 may be greater than the etching rate of the semiconductor material layer 12. In some embodiments, the depths of the openings 333, 334 may be greater than the depths of the openings 343, 344.

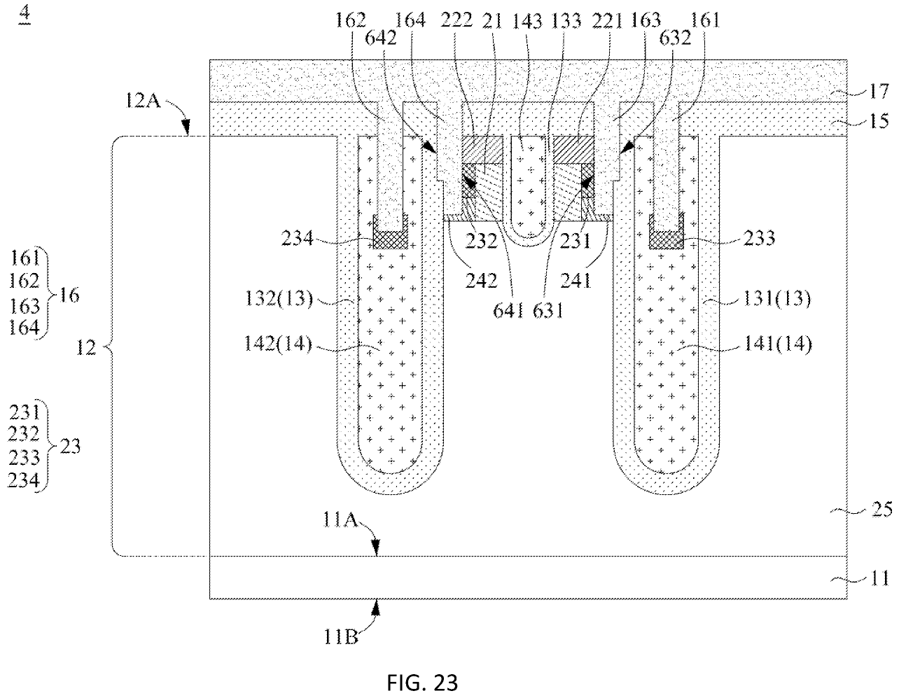

Referring to FIG. 23, the second manufacturing method includes forming the conductive plugs 16 in the openings 333, 334, 343, and 344. For the step of FIG. 23, please refer to the description of the step described with respect to FIG. 16. In some embodiments, after the openings 333, 334 are formed, an ion implantation process may be performed to form the heavily doped regions 233 and 234 in the shield electrodes 141 and 142.

The configurations/shapes of the conductive plugs 16 may be defined by the configurations/shapes of the openings 333, 334, 343, and 344, and thus the conductive plugs 161, 162, 163, 164 have the same configurations/shapes as the openings 333, 334, 343, and 344. In some embodiments, the width of the conductive plug 161 at the surface 12A is approximately the same as that of the bottom of the conductive plug 161. In some embodiments, the conductive plug 162 has a configuration/shape similar or identical to the conductive plug 161. In some embodiments, the conductive plug 163 has sidewalls 631, 632 opposite to each other, where the sidewall 631 is closer to the gate electrode 143 than the sidewall 632, and the sidewalls 631 and 632 have different lengths along the vertical direction. In some embodiments, the sidewall 631 is connected to the bottom of the conductive plug 163, and the sidewall 632 ends between the surface 12A and the bottom of the conductive plug 163. In some embodiments, the sidewall 632 ends in the in-trench dielectric layer 131. In some embodiments, the conductive plug 164 has sidewalls 641, 642 opposite to each other, where the sidewall 641 is closer to the gate electrode 143 than the sidewall 642, and the sidewalls 641, 642 have different lengths along the vertical direction. In some embodiments, the sidewall 641 is connected to the bottom of the conductive plug 164, and the sidewall 642 ends between the surface 12A and the bottom of the conductive plug 164. In some embodiments, the sidewall 642 ends in the in-trench dielectric layer 131.

The vertical power semiconductor device 4 formed through the above steps with respect to FIG. 17 to FIG. 23 may be the same as the vertical power semiconductor device 1 as shown in FIG. 1, and have the same functions. For the sake of brevity, in the following description, only the differences between different embodiments will be described, and relevant descriptions of structures or process methods that are the same as or similar to those of the previous embodiments will be omitted.

The patterns of the masks used to define the openings 331, 332, 341, 342 may be adjusted according to different embodiments, so the configurations/shapes of the conductive plugs 163, 164 and the relative positions of the conductive plugs 163, 164 in the doped regions 22, 23, 24 may be slightly different, which, however, does not affect the performance of the vertical power semiconductor devices of the embodiments of the present disclosure.

For example, in the steps of forming the openings 341, 342, there may be different patterned mask layers depending on the photomasks used, and thus the positions of the openings 341, 342 may differ from those described with respect to FIG. 21 or FIG. 10.

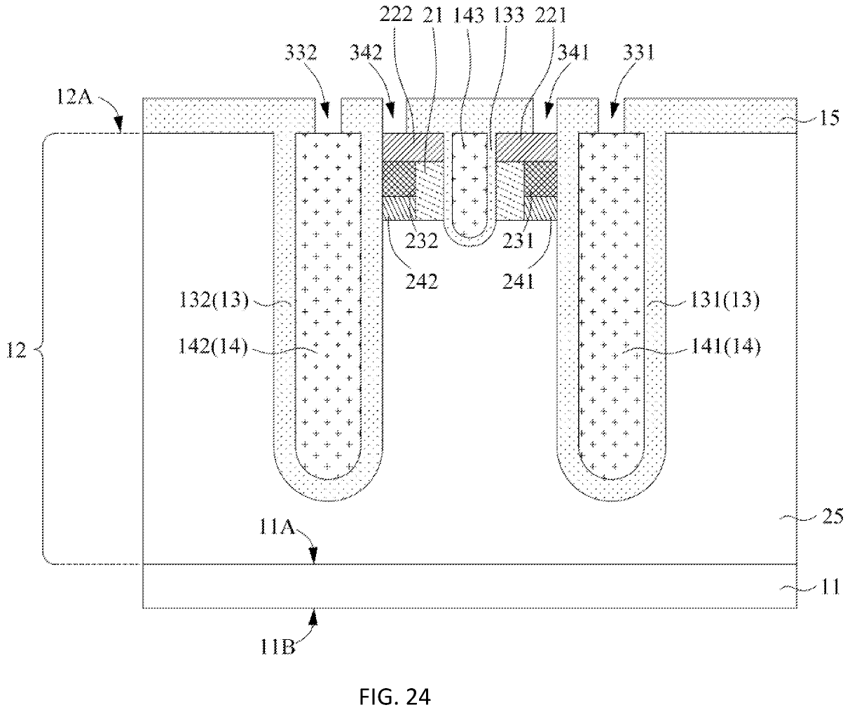

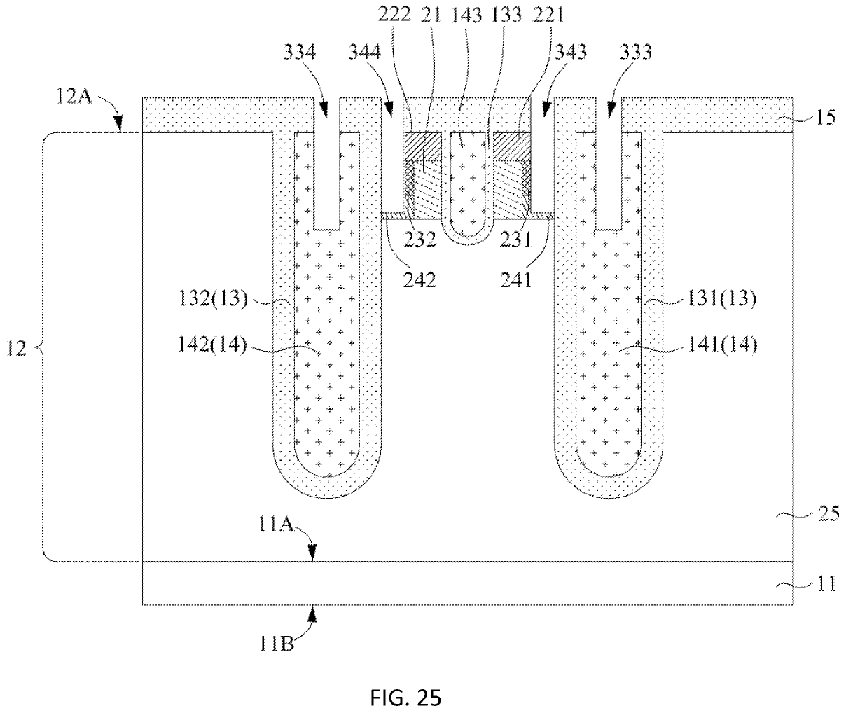

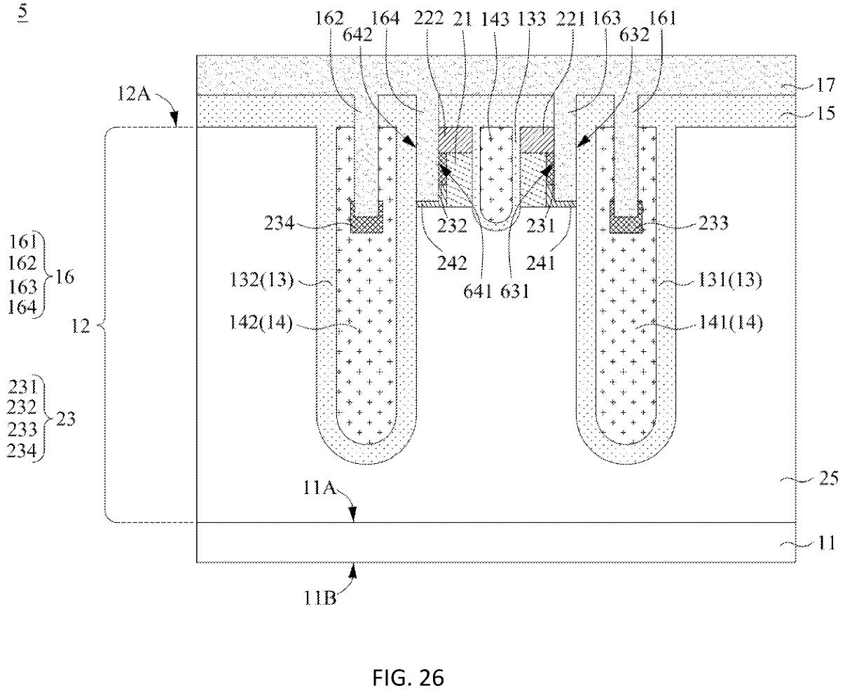

Referring to FIG. 24 to FIG. 26, in some embodiments, the sidewalls of the openings 341 and 342 may be aligned with the sidewalls of the in-trench dielectric layers 131 and 132, as shown in FIG. 24. In some embodiments, the openings 341, 342 may expose a portion of the surface 12A of semiconductor material layer 12, and may not expose the in-trench dielectric layers 131 and 132. The openings 333, 334, 343, 344 may be formed according to the aforementioned step described with respect to FIG. 22, as shown in FIG. 25. In some embodiments, the width of the opening 343 at the surface 12A may be approximately the same as the width of the bottoms of the openings 343, 344. In some embodiments, the opening 343 may adjoin a sidewall of the in-trench dielectric layer 131. In some embodiments, the in-trench dielectric layers 131 and 132 may be kept unchanged during the forming of the openings 341, 342 and the forming of the openings 343, 344, without being removed in the process. In some embodiments, the opening 344 may have a similar or identical shape to the opening 343. In some embodiments, the depths of the openings 333, 334 may be greater than the depths of the openings 343, 344. Then, according to the aforementioned steps of FIG. 23, the conductive plugs 16 may be formed in the openings 333, 334, 343, and 344, as shown in FIG. 26.

The configurations/shapes of the conductive plugs 16 are defined by the configurations of the openings 333, 334, 343, 344, and thus the conductive plugs 161, 162, 163, 164 have the same configurations/shapes as the openings 333, 334, 343, 344. In some embodiments, the conductive plug 163 may have sidewalls 631, 632 opposite to each other, where the sidewall 631 is closer to the gate electrode 143 than the sidewall 632, and the sidewalls 631, 632 have the same length along the vertical direction. In some embodiments, the sidewall 632 may be in contact with a sidewall of the in-trench dielectric layer 131. In some embodiments, the sidewalls 631, 632 may be respectively connected with opposite sides of the bottom of the conductive plug 163. In some embodiments, the conductive plug 164 has sidewalls 641 and 642 opposite to each other, where the sidewall 641 is closer to the gate electrode 143 than the sidewall 642, and the sidewalls 641 and 642 have the same length in the vertical direction. In some embodiments, the sidewalls 641, 642 may be connected respectively to opposite sides of the bottom of the conductive plug 164. In some embodiments, the sidewall 642 may be in contact with a sidewall of the in-trench dielectric layer 132.

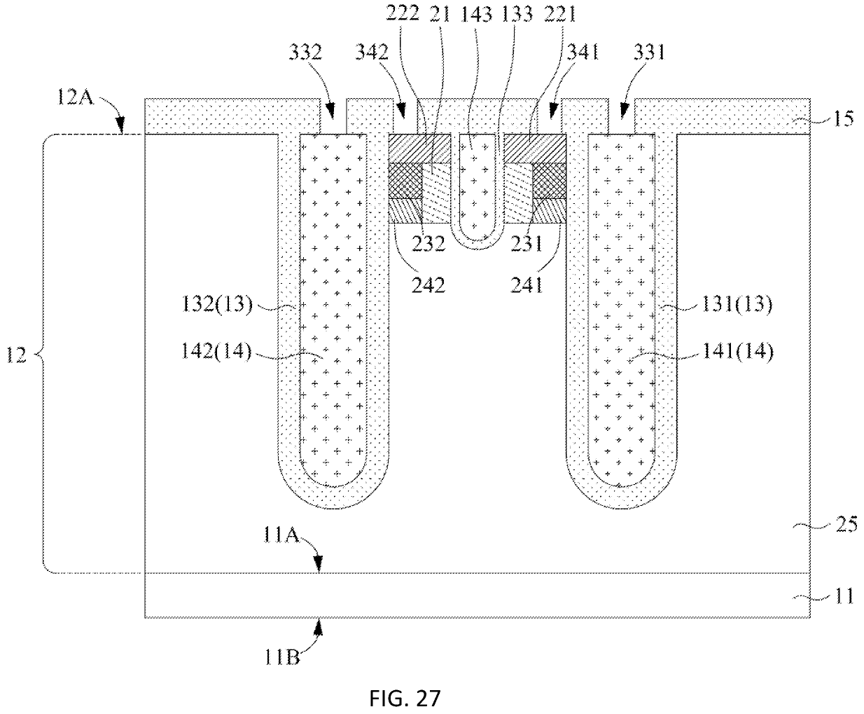

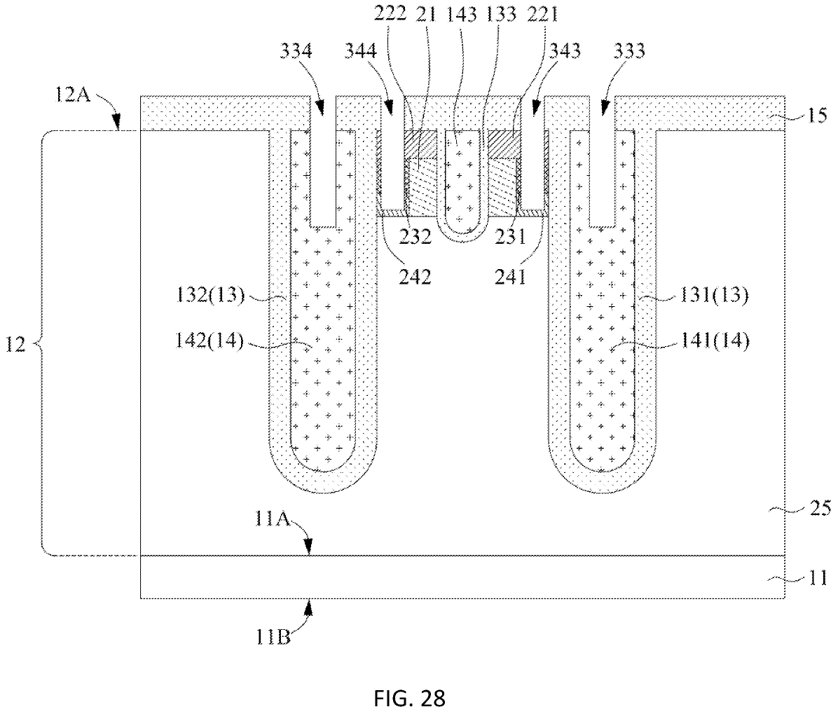

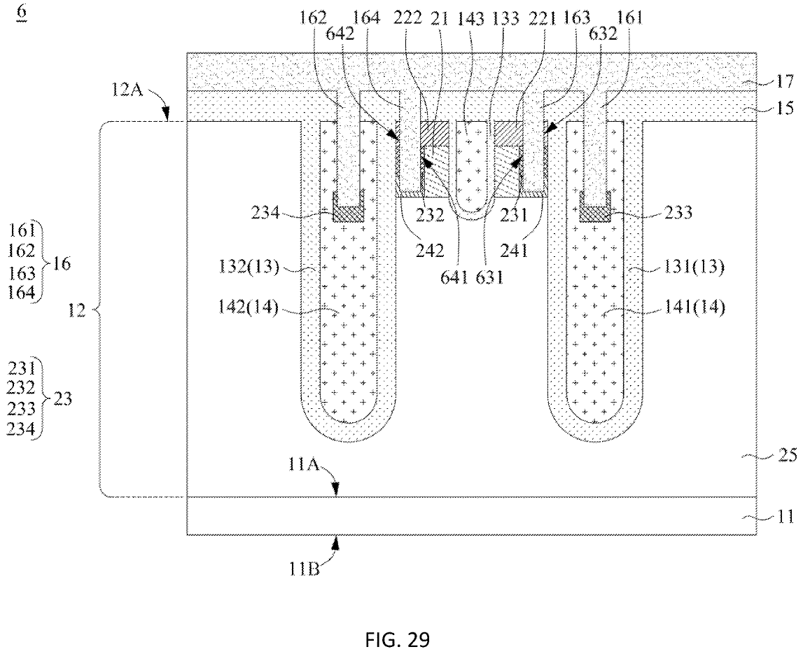

Referring to FIG. 27 to FIG. 29, in some embodiments, the openings 341, 342 overlap the doped region 23 or 22, and are separated from the in-trench dielectric layer 13 in the vertical direction, as shown in FIG. 27. According to the aforementioned steps of FIG. 22, the openings 333, 334, 343, 344 may be formed, as shown in FIG. 28 (i.e., the openings 331, 332, 341, 342 respectively as shown herein). In some embodiments, the width of the opening 343 at the surface 12A may be approximately the same as the width of the bottoms of the openings 343, 344. In some embodiments, the opening 343 may be disposed in the semiconductor material layer 12 and is separate from the in-trench dielectric layer 131. In some embodiments, the opening 344 may be disposed in the semiconductor material layer 12 and separate from the in-trench dielectric layer 132. In some embodiments, the in-trench dielectric layers 131, 132 remain unchanged during the forming of the openings 341, 342 and the openings 343, 344 without being removed during the process. In some embodiments, the opening 344 may have a configuration/shape that is similar to or the same as the opening 343. In some embodiments, the opening 333 may surrounded by the doped regions 221, 231, 241, and the opening 334 may be surrounded by the doped regions 222, 232, 242. Then, based on the aforementioned steps of FIG. 23, the conductive plugs 16 may be formed in the openings 333, 334, 343, and 344, as shown in FIG. 26.

The configurations/shapes of the conductive plugs 16 are defined by the configurations/shapes of the openings 333, 334, 343, 344, and thus, the conductive plugs 161, 162, 163, 164 may have the same configurations/shapes as the openings 333, 334, 343, 344. In some embodiments, the conductive plug 163 has sidewalls 631, 632 opposite to each other, where the sidewall 631 is closer to the gate electrode 143 than the sidewall 632, and the sidewall 632 is arranged in the doped regions 221, 231, 241 along the vertical direction. In some embodiments, the conductive plug 164 has opposing sidewalls 641, 642, where the sidewall 641 is closer to the gate electrode 143 than the sidewall 642, and sidewall 642 is arranged in the doped regions 222, 232, 242 along the vertical direction.

Under the conditions of the same specifications and processes, the semiconductor device 3 as described with respect to FIG. 16 and the semiconductor device 1 as described with respect to FIG. 1 have similar or same contact areas between the conductive plugs 16 and the SBD doped region 24; and compared with the semiconductor devices 4, 5, and 6 as described with respect to FIGS. 23, 26, and 29, the contact areas between the conductive plugs 16 and the SBD doped region 24 in the semiconductor devices 4, 5, and 6 are greater. Further, among the three semiconductor devices 4, 5, and 6, the contact areas between the conductive plugs 16 and the SBD doped region 24 vary according to the positions of the conductive plugs 16 that are defined by the photomasks. Specifically, for the contact areas between the conductive plugs 16 and the SBD doped region 24, the semiconductor device 6 may have a contact area larger than the semiconductor device 5, and the semiconductor device 5 may have a contact area larger than the semiconductor device 4.

In different embodiments of the present disclosure, the conduction voltage and leakage current of a semiconductor device may be adjusted by adjusting the contact area between the conductive plugs 16 and the SBD doped region 24. The smaller the contact area between the conductive plugs 16 and the SBD doped region 24, the smaller the leakage current and the larger the conduction voltage. Therefore, in embodiments where the contact area between the conductive plugs 16 and the SBD doped region 24 is smaller, although a higher voltage is required to control the switching of the switches, the leakage current problem will be smaller. On the contrary, the larger the contact area between the conductive plugs 16 and the SBD doped region 24, the smaller the conduction voltage and the larger the leakage current. Therefore, in embodiments where the contact area between the conductive plugs 16 and the SBD doped region 24 is larger, the turn-on voltage is smaller, and it is easier to control the switches of the semiconductor device, however, there will be relatively large leakage current. For different products having different requirements for the conduction current and leakage current, the contact area between the conductive plugs 16 and the SBD doped region 24 may be adjusted according to the different requirements.

In this disclosure, for description convenience, spatially relative terms such as “below”, “under”, “lower”, “above”, “upper”, “left side”, “right side”, and so on, may be used to describe the relationship of one component or feature with another one or more components or features, as shown in the accompanying drawings. The spatially relative terms are not only used to depict the orientations in the accompanying drawings, but also intended to encompass different orientations of the device in use or operation. A device may be oriented in other ways (rotated 90 degrees or at other orientations), and the spatially relative terms used herein may be interpreted in a corresponding way similarly. It should be understood that when a component is referred to as being “connected” or “coupled” to another component, it can be directly connected or coupled to another component or an intervening component may be present.

As used herein, the terms “approximately”, “basically”, “substantially” and “about” are used to describe and account for small variations. When used in conjunction with an event or instance, the terms may refer to an embodiment of exact occurrence of an event or instance as well as an embodiment where the event or instance is close to the occurrence. As used herein with respect to a given value or range, the term “about” generally means being within ±10%, ±5%, ±1%, or ±0.5% of the given value or range. A range herein may be referred to as being from one endpoint to the other or as being between two endpoints. All ranges disclosed herein are inclusive of the endpoints unless otherwise indicated. The term “substantially coplanar” may mean that the difference of positions of two surfaces with reference to the same plane is within a few micrometers (μm), e.g., within 10 μm, within 5 μm, within 1 μm, or within 0.5 μm. When values or characteristics are referred to as being “substantially” the same, the term may refer to a value that is within ±10%, ±5%, ±1%, or ±0.5% of the mean of the values.

The foregoing has outlined features of some embodiments and detailed aspects of present disclosure. The embodiments described in the present disclosure may be readily used as a basis for designing or modifying other processes and structures in order to carry out the same or similar purposes and/or to achieve the same or similar advantages of the embodiments presented herein. Such equivalent constructions do not depart from the spirit and scope of the present disclosure, and various changes, substitutions, and alterations can be made without departing from the spirit and scope of the present disclosure.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

What is claimed:

1. A vertical power semiconductor device, comprising:
a semiconductor material layer having a first surface and a second surface opposite to each other;
a first electrode structure, arranged in the semiconductor material layer and extending from the first surface to the second surface;
a second electrode structure, arranged in the semiconductor material layer and adjacent to the first electrode structure;
a conductive plug arranged between the first electrode structure and the second electrode structure;
a first doped region, arranged at least in the semiconductor material layer close to the first surface and between the first electrode structure and the second electrode structure, the first doped region having a first conductivity type;
a second doped region in the first doped region between the first electrode structure and the second electrode structure, the second doped region having a second conductivity type, and the second doped region being close to a bottom of the first doped region and separated from the first surface; and
a third doped region in the semiconductor material layer between the bottom of the first doped region and the second surface, the third doped region having the second conductivity type, a doping concentration of the second doped region being greater than a doping concentration of the third doped region, and the conductive plug being separated from the third doped region.

2. The vertical power semiconductor device according to claim 1, further comprising:
a fourth doped region between the first electrode structure and the second electrode structure and close to the first surface, a depth of the fourth doped region being smaller than a depth of the first doped region.

3. The vertical power semiconductor device according to claim 2, wherein the fourth doped region has the second conductive type, and a doping concentration of the fourth doped region is greater than a doping concentration of the first doped region or than the doping concentration of the second doped region.

4. The vertical power semiconductor device according to claim 2, wherein the conductive plug extends through the fourth doped region.

5. The vertical power semiconductor device according to claim 2, further comprising:
a fifth doped region between the second doped region and the fourth doped region, the fifth doped region adjoining the conductive plug and being separated from the second electrode structure, wherein the fifth doped region has the first conductivity type.

6. The vertical power semiconductor device according to claim 5, wherein a doping concentration of the fifth doped region is greater than the doping concentration of the second doped region or a doping concentration of the first doped region.

7. The vertical power semiconductor device according to claim 5, wherein a width of the fifth doped region is greater than a width of the second doped region.

8. The vertical power semiconductor device according to claim 5, wherein a width of the fifth doped region is approximately equal to a width of the second doped region.

9. The vertical power semiconductor device according to claim 1, wherein the conductive plug has a first sidewall and a second sidewall opposite to each other, the first sidewall being connected to a bottom of the conductive plug, and the second sidewall ending between the first surface and the bottom of the conductive plug.

10. The vertical power semiconductor device according to claim 9, wherein the first sidewall is close to the first electrode structure, and the second sidewall is away from the first electrode structure.

11. The vertical power semiconductor device according to claim 9, wherein the first sidewall is away from the first electrode structure, and the second sidewall is close to the first electrode structure.

12. The vertical power semiconductor device according to claim 1, wherein,
a depth of the second electrode structure is less than a depth of the first electrode structure and is greater than a depth of the first doped region, and
a distance from the conductive plug to the first electrode structures is less than a distance from the conductive plug to the second electrode structure.

13. A method for manufacturing a vertical power semiconductor device, comprising:
forming a first trench and a second trench in a semiconductor material layer, the semiconductor material layer comprising a lightly doped region of a first conductivity type;
forming a first electrode structure and a second electrode structure in the first trench and the second trench, respectively;
forming a first doped region, a second doped region and a third doped region in the semiconductor material layer between the first electrode structure and the second electrode structure, the first doped region having the first conductivity type and adjoining an upper surface of the semiconductor material layer, the second doped region having a second conductivity type and adjoining a bottom of the first doped region, the third doped region having the first conductivity type and adjoining a bottom of the second doped region, a doping concentration of the third doped region being greater than a doping concentration of the lightly doped region; and
forming a conductive plug between the first electrode structure and the second electrode structure, the conductive plug extending downward from the upper surface of the semiconductor material layer and contacting the first doped region, the second doped region and the third doped region, and the conductive plug ending in the third doped region and being separated from the lightly doped region.

14. The method according to claim 13, wherein forming the first electrode structure and the second electrode structure in the first trench and the second trench respectively comprises:
forming a first in-trench dielectric layer and a first shield electrode in the first trench, the first shield electrode being surrounded by the first in-trench dielectric layer; and
forming a second in-trench dielectric layer and a second shield electrode in the second trench, the second shield electrode being surrounded by the second in-trench dielectric layer.

15. The method according to claim 13, wherein forming the conductive plug between the first electrode structure and the second electrode structure comprises:
forming a third trench in at least a portion of the semiconductor material layer; and
filling the third trench with a conductive material.

16. The method according to claim 15, wherein forming the first doped region, the second doped region and the third doped region is performed before forming the third trench in at least the portion of the semiconductor material layer.

17. The method according to claim 16, wherein forming the first doped region, the second doped region and the third doped region comprises:
forming the third doped region between the first electrode structure and the second electrode structure, the third doped region being in contact with the first electrode structure and separated from the second electrode structure;
forming the second doped region between the first electrode structure and the second electrode structure and above the third doped region, the second doped region being in contact with the first electrode structure and separated from the second electrode structure; and
forming the first doped region between the first electrode structure and the second electrode structure and above the second doped region, the first doped region being in contact with the first electrode structure and the second electrode structure.

18. The method according to claim 17, wherein forming the third trench in at least the portion of the semiconductor material layer comprises:
performing etching in the semiconductor material layer, the etching ending in the third doped region.

19. The method according to claim 15, wherein,
forming the third trench in at least the portion of the semiconductor material layer comprises a plurality of steps, and
forming the first doped region, the second doped region and the third doped region in the semiconductor material layer between the first trench and the second trench and the plurality of steps are performed alternately.

20. The method according to claim 19, further comprising:
forming a fourth doped region in the semiconductor material layer between the first electrode structure and the second electrode structure, the fourth doped region having the second conductivity type;
forming the first doped region in the semiconductor material layer between the first electrode structure and the second electrode structure, the first doped region having a depth less than that of the fourth doped region;
forming an interlayer dielectric layer on the upper surface of the semiconductor material layer;
performing a first etching to remove a portion of the interlayer dielectric layer above the first doped region and to remove a first portion of a first in-trench dielectric layer of the first electrode structure adjoining the semiconductor material layer;
performing a second etching to partially remove an exposed portion of the semiconductor material layer, the second etching ending in the fourth doped region below the first doped region;
performing a first ion implantation to form the second doped region;
performing a third etching to partially remove a second portion of the first in-trench dielectric layer of the first electrode structure adjoining the semiconductor material layer, the third etching ending above a bottom of the fourth doped region, and the fourth doped region being below the second doped region; and
performing a second ion implantation to form the third doped region.

21. The method according to claim 20, wherein forming the first doped region is performed before forming the interlayer dielectric layer.

22. The method according to claim 20, further comprising:
performing a first annealing process after the first ion implantation is performed; and
performing a second annealing process after the second ion implantation is performed.

23. The method according to claim 20, wherein the third doped region contacts or passes through a bottom of the fourth doped region.
